(19) United States
(12) Patent Application Publication
(10) Pub. No.: US 2024/0159847 A1
(43) Pub. Date: May 16, 2024

(54) SYSTEMS AND METHODS FOR MAGNETIC RESONANCE IMAGING

(71) Applicant: SHANGHAI UNITED IMAGING HEALTHCARE CO., LTD., Shanghai (CN)

(72) Inventors: Xuchen ZHU, Shanghai (CN); Rongxing ZHANG, Shanghai (CN)

(73) Assignee: SHANGHAI UNITED IMAGING HEALTHCARE CO., LTD., Shanghai (CN)

(21) Appl. No.: 18/419,584

(22) Filed: Jan. 23, 2024

Related U.S. Application Data
(63) Continuation of application No. PCT/CN2022/109062, filed on Jul. 29, 2022.

(30) Foreign Application Priority Data
Jul. 30, 2021 (CN) 202110871827.X
Aug. 4, 2021 (CN) 202110892318.5

(51) Int. Cl. G01R 33/54; G01R 33/36

(52) U.S. Cl. CPC G01R 33/54; G01R 33/3607

(57) ABSTRACT

A system and method for MRI are provided. a plurality of RF parameters for an MRI scan, using an MRI scanner, of a subject may be obtained. A first power loss and a first current square factor of the RF coil assembly under an unloaded condition of the MRI scanner may be determined based on the plurality of RF parameters. A total power loss of the MRI scan and a second current square factor of the RF coil assembly during the MRI scan may be determined based on the plurality of RF parameters. A second power loss of the RF coil assembly during the MRI scan may be determined based on the first power loss, the first current square factor, and the second current square factor. A SAR of the subject during the MRI scan may be determined based on the total power loss and the second power loss.

### CROSS-REFERENCE TO RELATED APPLICATIONS

This application is a continuation of International Application No. PCT/CN2022/109062, filed on Jul. 29, 2022, which claims priority to Chinese Application No. 202110892318.5, filed on Aug. 04, 2021, and Chinese Application No. 202110871827.X, filed on Jul. 30, 2021, the contents of each of which are incorporated herein by reference in their entirety.

### TECHNICAL FIELD

The present disclosure relates to imaging, and more particularly, relates to systems and methods for magnetic resonance imaging (MRI).

### BACKGROUND

MRI is a widely used medical imaging technique that uses a magnetic field and radiofrequency (RF) signals to acquire information of anatomy and/or physiological information of a patient body. With the development of MRI technology, an RF coil assembly including multiple RF coils is widely used in the MRI.

### SUMMARY

According to an aspect of the present disclosure, a system may be provided. The system may include at least one storage device and at least one processor configured to communicate with the at least one storage device. The at least one storage device may include a set of instructions. When the at least one processor execute the set of instructions, the at least one processor may be directed to cause the system to perform one or more of the following operations. The system may obtain a plurality of RF parameters for an MRI scan, using an MRI scanner, of a subject, the plurality of RF parameters including at least one RF parameter of an RF waveform to be transmitted into each of a plurality of system channels of the MRI scanner. Each of the plurality of system channels may be connected to one of a plurality of coil channels of an RF coil assembly of the MRI scanner to form an RF channel. The system may also determine a first power loss and a first current square factor of the RF coil assembly under an unloaded condition of the MRI scanner based on the plurality of RF parameters. The system may also determine a total power loss of the MRI scan and a second current square factor of the RF coil assembly during the MRI scan based on the plurality of RF parameters. The system may also determine a second power loss of the RF coil assembly during the MRI scan based on the first power loss, the first current square factor, and the second current square factor. The system may further determine based on the total power loss and the second power loss, a specific absorption ratio (SAR) of the subject during the MRI scan.

In some embodiments, to determine a first power loss and a first current square factor of the RF coil assembly under an unloaded condition of the MRI scanner based on the plurality of RF parameters, the system may obtain a first forward coefficient associated with forward signals of the RF coil assembly, a first reverse coefficient associated with reverse signals of the RF coil assembly, and a first coupling coefficient associated with coupling signals of the RF coil assembly. The system may further determine the first power loss and the first current square factor based on the plurality of RF parameters, the first forward coefficient, the first reverse coefficient, and the first coupling coefficient.

In some embodiments, to obtain a first forward coefficient associated with forward signals of the RF coil assembly, a first reverse coefficient associated with reverse signals of the RF coil assembly, and a first coupling coefficient associated with coupling signals of the RF coil assembly, the system may obtain a plurality of first RF parameter vectors. The plurality of first RF parameter vectors may be linearly independent. An element of each of the plurality of first RF parameter vectors may include RF parameters of an RF waveform to be transmitted into one of the plurality of system channels. For each of the plurality of first RF parameter vectors, the system may obtain first reference forward signals, first reference reverse signals, and first reference coupling signals corresponding to the plurality of coil channels by performing, based on the first RF parameters vector, a first reference MRI scan under the unloaded condition of the MRI scanner. The system may determine the first forward coefficient, the first reverse coefficient, and the first coupling coefficient based on the first reference forward signals, the first reference reverse signals, and the first reference coupling signals corresponding to the plurality of first RF parameter vectors.

In some embodiments, the plurality of first RF parameter vectors may form a first diagonal matrix.

In some embodiments, to determine a total power loss of the MRI scan and a second current square factor of the RF coil assembly based on the plurality of RF parameters, the system may determine a second forward coefficient associated with forward signals of the RF coil assembly, a second reverse coefficient associated with reverse signals of the RF coil assembly, and a second coupling coefficient associated with coupling signals of the RF coil assembly. The system may determine the total power loss of the MRI scan and the second current square factor of the RF coil assembly based on the plurality of RF parameters, the second forward coefficient, the second reverse coefficient, and the second coupling coefficient.

In some embodiments, to obtain a second forward coefficient associated with forward signals of the RF coil assembly, a second reverse coefficient associated with reverse signals of the RF coil assembly, and a second coupling coefficient associated with coupling signals of the RF coil assembly, the system may obtain a plurality of second RF parameter vectors. The plurality of second RF parameter vectors may be linearly independent. An element of each of the plurality of second RF parameters vectors may include RF parameters of an RF waveform to be transmitted into one of the plurality of system channels. For each of the plurality of second RF parameters vectors, the system may obtain second reference forward signals, second reference reverse signals, and second reference coupling signals corresponding to the plurality of coil channels by performing, based on the second RF parameter vector, a second reference MRI scan on the subject using the MRI scanner. The system may determine the second forward coefficient, the second reverse coefficient, and the second coupling coefficient based on the second reference forward signals, the second reference reverse signals, and the second reference coupling signals corresponding to the plurality of second RF parameter vectors.

In some embodiments, the plurality of second RF parameter vectors may form a second diagonal matrix.

In some embodiments, to determine a total power loss of the MRI scan and a second current square factor of the RF coil assembly based on the plurality of RF parameters, the system may determine whether the plurality of RF parameters satisfy a preset condition. In response to determining that the plurality of RF parameters satisfy the preset condition, the system may obtain forward signals, reverse signals, and coupling signals corresponding to the plurality of coil channels collected during the MRI scan of the subject. The system may determine the total power loss of the MRI scan and the second current square factor of the RF coil assembly based on the forward signals, the reverse signals, and the coupling signals corresponding to the plurality of coil channels.

In some embodiments, the at least one RF parameter of an RF waveform to be transmitted into each of the plurality of system channels may include an amplitude value and a phase value of the RF waveform to be transmitted into the system channel. The preset condition may include a ratio between amplitude values of the system channel and the coil channel of each RF channel of the plurality of RF channels is the same among the plurality of RF channels during the MRI scan, and a difference between phase values of the system channel and the coil channel of each RF channel of the plurality of system channels is the same among the plurality of RF channels during the MRI scan.

In some embodiments, the at least one processor may be further directed to cause the system to perform the following operations. In response to determining that a value of the SAR of the subject exceeds a threshold, the system may adjust the plurality of RF parameters.

According to another aspect of the present disclosure, a system may be provided. The system may include at least one storage device and at least one processor configured to communicate with the at least one storage device. The at least one storage device may include a set of instructions. When the at least one processor execute the set of instructions, the at least one processor may be directed to cause the system to perform one or more of the following operations. The system may obtain a plurality of RF parameter vectors for an MRI scan using an MRI scanner. The plurality of RF parameter vectors may be linearly independent. An element of each of the plurality of RF parameter vectors may include RF parameters of an RF waveform to be transmitted into one of a plurality of system channels of the MRI scanner. For each of the plurality of RF parameter vectors, the system may obtain forward signals, reverse signals, and coupling signals corresponding to a plurality of coil channels of an RF coil assembly of the MRI scanner by performing, based on the RF parameters vector, an MRI scan under an unloaded condition of the MRI scanner. The system may further determine a forward coefficient associated with forward signals of the RF coil assembly, a reverse coefficient associated with reverse signals of the RF coil assembly, and a coupling coefficient associated with coupling signals of the RF coil assembly based on the forward signals, the reverse signals, and the coupling signals corresponding to the plurality of RF parameter vectors.

According to yet another aspect of the present disclosure, a system may be provided. The system may include an RF generator, an RF coil assembly, a plurality of directional couplers, and a plurality of coupling probes. The RF generator may include a plurality of system channels, configured to generate, based on a plurality of RF parameters, RF waveforms. The RF coil assembly may be configured to generate RF excitation pulses by applying the RF waveforms to the RF coil assembly to perform, using an MRI scanner, an MRI scan. The RF coil assembly may include a plurality of coil channels. Each coil channel of the plurality of coil channels may correspond to one coil of a plurality of coils of the RF coil assembly and is operably connected to one system channel of the plurality of system channels. The plurality of directional couplers may be configured to collect forward signals and/or reverse signals of the RF coil assembly during the MRI scan, wherein each of the plurality of directional couplers is arranged between the RF generator and one coil of the plurality of coils of the RF coil assembly. The plurality of coupling probes may be configured to collect coupling signals of the RF coil assembly during the MRI scan.

In some embodiments, the system may further include a plurality of RF power amplifiers operably connected to the RF generator. The plurality of RF power amplifiers may be configured to amplify the RF waveforms and transmit the amplified RF waveforms to the RF coil assembly.

In some embodiments, the system may further include a processing device. The processing device may be configured to determine a power loss of the RF coil assembly during the MRI scan based on the forward signals, the reverse signals, and the coupling signals of the RF coil assembly.

In some embodiments, the processing device may include an analog-to-digital converter. The analog-to-digital converter may be configured to obtain forward data, reverse data, and coupling data of the RF coil assembly by performing analog-to-digital conversions on the forward signals, the reverse signals, and the coupling signals of the RF coil assembly.

In some embodiments, the MRI scan may be performed on a subject, and the processing device may be configured to determine a specific absorption ratio (SAR) of the subject during the MRI of the subject based on the power loss of the RF coil assembly.

In some embodiments, the system may further include a controller. The controller may be configured to control resonance or detuning of the RF coil assembly, or adjust the plurality of RF parameters according to the SAR of the subject.

According to yet another aspect of the present disclosure, a system may be provided. The system may include at least one storage device and at least one processor configured to communicate with the at least one storage device. The at least one storage device may include a set of instructions. When the at least one processor execute the set of instructions, the at least one processor may be directed to cause the system to perform one or more of the following operations. The system may obtain a plurality of sets of image data each of which is acquired by performing an MRI scan using an MRI scanner. Each system channel of a plurality of system channels of the MRI scanner may be capable of being operably connected with any one coil channel of the plurality of coil channels of an RF coil assembly of the MRI scanner to form one of a plurality of RF channels of the MRI scanner. The system may determine at least one of a first relationship between RF waveforms of the plurality of system channels and a second relationship between RF excitation pulses of the plurality of coil channels based on the plurality of sets of image data. The first relationship and the second relationship may be configured to provide a plurality of RF parameters for an MRI scan using the MRI scanner.

In some embodiments, the plurality of sets of image data may include MR signals, image data in an image domain, or image data in a k-space.

In some embodiments, to obtain a plurality of sets of image data each of which is acquired by performing an MRI scan using a magnetic resonance (MR) scanner, for each of the plurality of sets of image data, the system may acquire the set of image data by transmitting a reference RF waveform via one of the plurality of RF channels.

In some embodiments, the reference RF waveforms for acquiring the plurality of sets of image data may have a same amplitude value and a same phase value.

In some embodiments, each of the plurality of sets of image data may include amplitude information, the first relationship may include a first amplitude gain relationship between amplitude gains of the RF waveforms of the plurality of system channels. The second relationship may include a second amplitude gain relationship between amplitude gains of the RF excitation pulses of the plurality of coil channels.

In some embodiments, each of the plurality of sets of image data include phase information, the first relationship may include a first phase relationship between phase values of the RF waveforms of the plurality of system channels. The second relationship may include a second phase relationship between phase values of the RF excitation pulses of the plurality of coil channels.

In some embodiments, the at least one processor may be further directed to cause the system to perform the following operations. The system may obtain a plurality of initial RF parameters for a target MRI scan of a subject using the MRI scanner. The system may determine a plurality of target RF parameters for the target MRI scan based on the plurality of initial RF parameters, the first relationship, and the second relationship.

According to yet another aspect of the present disclosure, a system may be provided. The system may include at least one storage device and at least one processor configured to communicate with the at least one storage device. The at least one storage device may include a set of instructions. When the at least one processor execute the set of instructions, the at least one processor may be directed to cause the system to perform one or more of the following operations. The system may obtain a plurality of initial RF parameters for an MRI scan, using an MRI scanner, of a subject. The MRI scanner may include a plurality of system channels and an RF coil assembly. The RF coil assembly may include a plurality of coils each of which corresponds to a coil channel. Each system channel of the plurality of system channels may be capable of being operably connected with any one coil channel of the plurality of coil channels of the RF coil assembly to form one of a plurality of RF channels of the MRI scanner. The system may obtain a first relationship between RF waveforms of the plurality of system channels and a second relationship between RF excitation pulses of the plurality of coil channels. The system may determine a plurality of target RF parameters for the MRI scan based on the plurality of initial RF parameters, the first relationship, and the second relationship. The plurality of target RF parameters may include at least one of a target amplitude value and a target phase value of an RF waveform to be transmitted into a target system channel of each of a plurality of target RF channels for performing the MRI scan.

According to yet another aspect of the present disclosure, a method may be provided. The method may include obtaining a plurality of RF parameters for an MRI scan, using an MRI scanner, of a subject. The plurality of RF parameters may include at least one RF parameter of an RF waveform to be transmitted into each of a plurality of system channels of the MRI scanner. Each of the plurality of system channels may be connected to one of a plurality of coil channels of an RF coil assembly of the MRI scanner to form an RF channel. The method may include determine a first power loss and a first current square factor of the RF coil assembly under an unloaded condition of the MRI scanner based on the plurality of RF parameters. The method may also include determine a total power loss of the MRI scan and a second current square factor of the RF coil assembly during the MRI scan based on the plurality of RF parameters. The method may also include determine a second power loss of the RF coil assembly during the MRI scan based on the first power loss, the first current square factor, and the second current square factor. The method may further include determine a SAR of the subject during the MRI scan based on the total power loss and the second power loss.

According to yet another aspect of the present disclosure, a method may be provided. The method may include obtaining a plurality of RF parameter vectors for an MRI scan using an MRI scanner. The plurality of RF parameter vectors may be linearly independent. An element of each of the plurality of RF parameter vectors may include RF parameters of an RF waveform to be transmitted into one of a plurality of system channels of the MRI scanner. The method may include, for each of the plurality of RF parameter vectors, obtaining forward signals, reverse signals, and coupling signals corresponding to a plurality of coil channels of an RF coil assembly of the MRI scanner by performing, based on the RF parameters vector, an MRI scan under an unloaded condition of the MRI scanner. The method may further include determining a forward coefficient associated with forward signals of the RF coil assembly, a reverse coefficient associated with reverse signals of the RF coil assembly, and a coupling coefficient associated with coupling signals of the RF coil assembly based on the forward signals, the reverse signals, and the coupling signals corresponding to the plurality of RF parameter vectors.

According to yet another aspect of the present disclosure, a method may be provided. The method may include obtaining a plurality of sets of image data each of which is acquired by performing an MRI scan using an MRI scanner. Each system channel of a plurality of system channels of the MRI scanner may be capable of being operably connected with any one coil channel of the plurality of coil channels of an RF coil assembly of the MRI scanner to form one of a plurality of RF channels of the MRI scanner. The method may further include determining at least one of a first relationship between RF waveforms of the plurality of system channels and a second relationship between RF excitation pulses of the plurality of coil channels based on the plurality of sets of image data. The first relationship and the second relationship may be configured to provide a plurality of RF parameters for an MRI scan using the MRI scanner.

According to yet another aspect of the present disclosure, a method may be provided. The method may include obtaining a plurality of initial RF parameters for an MRI scan, using an MRI scanner, of a subject. The MRI scanner may include a plurality of system channels and an RF coil assembly. The RF coil assembly may include a plurality of coils each of which corresponds to a coil channel. Each system channel of the plurality of system channels may be capable of being operably connected with any one coil channel of the plurality of coil channels of the RF coil assembly to form one of a plurality of RF channels of the MRI scanner. The method may also include obtaining a first relationship between RF waveforms of the plurality of system channels and a second relationship between RF excitation pulses of the plurality of coil channels. The method may further include determining a plurality of target RF parameters for the MRI scan based on the plurality of initial RF parameters, the first relationship, and the second relationship. The plurality of target RF parameters may include at least one of a target amplitude value and a target phase value of an RF waveform to be transmitted into a target system channel of each of a plurality of target RF channels for performing the MRI scan.

According to yet another aspect of the present disclosure, a non-transitory computer readable medium may be provided. The non-transitory computer readable medium may include at least one set of instructions. When the at least one set of instructions executed by one or more processors of a computing device, the at least one set of instructions may cause the computing device to perform a method. The method may include obtaining a plurality of RF parameters for an MRI scan, using an MRI scanner, of a subject. The plurality of RF parameters may include at least one RF parameter of an RF waveform to be transmitted into each of a plurality of system channels of the MRI scanner. Each of the plurality of system channels may be connected to one of a plurality of coil channels of an RF coil assembly of the MRI scanner to form an RF channel. The method may include determine a first power loss and a first current square factor of the RF coil assembly under an unloaded condition of the MRI scanner based on the plurality of RF parameters. The method may also include determine a total power loss of the MRI scan and a second current square factor of the RF coil assembly during the MRI scan based on the plurality of RF parameters. The method may also include determine a second power loss of the RF coil assembly during the MRI scan based on the first power loss, the first current square factor, and the second current square factor. The method may further include determine a SAR of the subject during the MRI scan based on the total power loss and the second power loss.

According to yet another aspect of the present disclosure, a non-transitory computer readable medium may be provided. The non-transitory computer readable medium may include at least one set of instructions. When the at least one set of instructions executed by one or more processors of a computing device, the at least one set of instructions may cause the computing device to perform a method. The method may include obtaining a plurality of RF parameter vectors for an MRI scan using an MRI scanner. The plurality of RF parameter vectors may be linearly independent. An element of each of the plurality of RF parameter vectors may include RF parameters of an RF waveform to be transmitted into one of a plurality of system channels of the MRI scanner. The method may include, for each of the plurality of RF parameter vectors, obtaining forward signals, reverse signals, and coupling signals corresponding to a plurality of coil channels of an RF coil assembly of the MRI scanner by performing, based on the RF parameters vector, an MRI scan under an unloaded condition of the MRI scanner. The method may further include determining a forward coefficient associated with forward signals of the RF coil assembly, a reverse coefficient associated with reverse signals of the RF coil assembly, and a coupling coefficient associated with coupling signals of the RF coil assembly based on the forward signals, the reverse signals, and the coupling signals corresponding to the plurality of RF parameter vectors.

According to yet another aspect of the present disclosure, a non-transitory computer readable medium may be provided. The non-transitory computer readable medium may include at least one set of instructions. When the at least one set of instructions executed by one or more processors of a computing device, the at least one set of instructions may cause the computing device to perform a method. The method may include obtaining a plurality of sets of image data each of which is acquired by performing an MRI scan using an MRI scanner. Each system channel of a plurality of system channels of the MRI scanner may be capable of being operably connected with any one coil channel of the plurality of coil channels of an RF coil assembly of the MRI scanner to form one of a plurality of RF channels of the MRI scanner. The method may further include determining at least one of a first relationship between RF waveforms of the plurality of system channels and a second relationship between RF excitation pulses of the plurality of coil channels based on the plurality of sets of image data. The first relationship and the second relationship may be configured to provide a plurality of RF parameters for an MRI scan using the MRI scanner.

According to yet another aspect of the present disclosure, a non-transitory computer readable medium may be provided. The non-transitory computer readable medium may include at least one set of instructions. When the at least one set of instructions executed by one or more processors of a computing device, the at least one set of instructions may cause the computing device to perform a method. The method may include obtaining a plurality of initial RF parameters for an MRI scan, using an MRI scanner, of a subject. The MRI scanner may include a plurality of system channels and an RF coil assembly. The RF coil assembly may include a plurality of coils each of which corresponds to a coil channel. Each system channel of the plurality of system channels may be capable of being operably connected with any one coil channel of the plurality of coil channels of the RF coil assembly to form one of a plurality of RF channels of the MRI scanner. The method may also include obtaining a first relationship between RF waveforms of the plurality of system channels and a second relationship between RF excitation pulses of the plurality of coil channels. The method may further include determining a plurality of target RF parameters for the MRI scan based on the plurality of initial RF parameters, the first relationship, and the second relationship. The plurality of target RF parameters may include at least one of a target amplitude value and a target phase value of an RF waveform to be transmitted into a target system channel of each of a plurality of target RF channels for performing the MRI scan.

Additional features will be set forth in part in the description which follows, and in part will become apparent to those skilled in the art upon examination of the following and the accompanying drawings or may be learned by production or operation of the examples. The features of the present disclosure may be realized and attained by practice or use of various aspects of the methodologies, instrumentalities, and combinations set forth in the detailed examples discussed below.

### BRIEF DESCRIPTION OF THE DRAWINGS

The present disclosure is further described in terms of exemplary embodiments. These exemplary embodiments are described in detail with reference to the drawings.

These embodiments are non-limiting exemplary embodiments, in which like reference numerals represent similar structures throughout the several views of the drawings, and wherein:

FIG. 1 is a schematic diagram illustrating an exemplary magnetic resonance imaging (MRI) system 100 according to some embodiments of the present disclosure;

FIG. 2 is a block diagram illustrating an exemplary processing device 120 according to some embodiments of the present disclosure;

FIG. 3 and FIG. 4 are schematics illustrating an exemplary RF transmit system 300 of an MRI system according to some embodiments of the present disclosure;

FIG. 5A is a schematic illustrating an exemplary RF coil assembly 320 according to some embodiments of the present disclosure;

FIG. 5B provides a schematic illustrating an exemplary coil loop according to some embodiments of the present disclosure;

FIG. 6 illustrates a measurement of a current signal of a coil using a coupling probe according to some embodiments of the present disclosure;

FIG. 7 is a flowchart illustrating an exemplary process 700 for determining an SAR of a subject during an MRI scan of the subject according to some embodiments of the present disclosure;

FIG. 8 is a flowchart illustrating an exemplary process 800 for determining a forward coefficient, a reverse coefficient, and a coupling coefficient according to some embodiments of the present disclosure;

FIG. 9 is a flowchart illustrating an exemplary process 900 for determining a second forward coefficient, a second reverse coefficient, and a second coupling coefficient according to some embodiments of the present disclosure according to some embodiments of the present disclosure;

FIG. 10 is a flowchart illustrating an exemplary process 1000 for calibrating relationships between RF signals of channels for transmitting RF signals according to some embodiments of the present disclosure;

FIG. 11 is a schematic illustrating an exemplary coil channels and system channels of an MRI scanner according to some embodiments of the present disclosure;

FIG. 12A is a schematic illustrating exemplary RF channels of an MRI scanner according to some embodiments of the present disclosure;

FIG. 12B is a schematic illustrating exemplary RF channels of an MRI scanner according to some embodiments of the present disclosure; and

FIG. 13 is a flowchart illustrating an exemplary process 1300 for determining a plurality of target RF parameters for an MRI scan of a subject according to some embodiments of the present disclosure.

### DETAILED DESCRIPTION

In the following detailed description, numerous specific details are set forth by way of examples in order to provide a thorough understanding of the relevant disclosure. However, it should be apparent to those skilled in the art that the present disclosure may be practiced without such details. In other instances, well-known methods, procedures, systems, components, and/or circuitry have been described at a relatively high level, without detail, in order to avoid unnecessarily obscuring aspects of the present disclosure. Various modifications to the disclosed embodiments will be readily apparent to those skilled in the art, and the general principles defined herein may be applied to other embodiments and applications without departing from the spirit and scope of the present disclosure. Thus, the present disclosure is not limited to the embodiments shown, but to be accorded the widest scope consistent with the claims.

During an MRI scan of a subject using an MRI scanner, the subject can absorb a portion of RF energy emitted from the MRI scanner for performing the MRI scan of the subject. This may cause body tissue to heat, which in turn may cause one or more side effects including, for example, body burns, vision loss, hearing loss, and nerve function loss. Thus, it is desired to provide systems and methods for accurately determining a specific absorption ratio (SAR) of a subject during an MRI scan of the subject.

The MRI scanner may include a plurality of RF channels. An RF channel may include one system channel of a plurality of system channels and one coil channel of a plurality of coil channels of an RF coil assembly including multiple RF coils. As used herein, an RF signal transmitted via a system channel refers to an RF waveform, and an RF signal transmitted via a coil channel I refers to an RF excitation pulse. An RF symmetry may usually be performed on the subject in the RF transmit system of the MRI scanner. After the RF symmetry is performed, an amplitude value and a phase value, etc., of the RF signal of each RF channel may vary with time, so that an image with a relatively good quality can be obtained. However, in this case, a power loss of the RF coil assembly may also change with a change in the amplitude value and the phase value, etc., of the RF signal of each RF channel, and so it is difficult to accurately assess the power loss of the RF coil assembly at any amplitude value and phase value.

Due to these and other difficulties, a total power loss for an MRI scan of a subject using an MRI scanner is conventionally considered as a power absorbed by the subject during the MRI scan of the subject, which has overlooked the power loss occurred in the RF coil assembly of the MRI scanner. Hence, an SAR of the subject during the MRI determined based on the power absorbed by the subject has a low accuracy.

An aspect of the present disclosure relates to systems and methods for determining an SAR of a subject during an MRI scan of the subject using an MRI scanner. The systems may obtain a plurality of RF parameters for the MRI scan of the subject. The plurality of RF parameters may include at least one RF parameter of an RF waveform to be transmitted into each of the plurality of system channels. An RF channel of the MRI scanner may be formed by one of a plurality of system channels and one of a plurality of coil channels of an RF coil assembly of the MRI scanner that are operably connected for the MRI scan. The systems may determine, based on the plurality of RF parameters, a first power loss and a first current square factor of the RF coil assembly under an unloaded condition of the MRI scanner. The systems may also determine, based on the plurality of RF parameters, a total power loss of the MRI scan and a second current square factor of the RF coil assembly during the MRI scan. The systems may also determine a second power loss of the RF coil assembly during the MRI scan based on the first power loss, the first current square factor, and the second current square factor. The systems may further determine the SAR of the subject during the MRI scan based on the total power loss and the second power loss. Compared with the conventional approach for determining an SAR of a subject, systems and methods of embodiments of the preset disclosure may obtain a more accurate SAR of the subject by taking into consideration of the power loss that has occurred in the RF coil assembly during the MRI scan, which in turn may allow a more effective and accurate monitoring of the safety of the subject during the MRI scan and/or an operation of the MRI scanner to a wider range within its full capacity.

An MRI scanner may include a plurality of system channels and a plurality of coil channels. In some embodiments, the connections between one or more system channels each with one of the plurality of coil channels may change, and therefore the MRI scanner may operate under various connection modes. As used herein, a connection mode corresponds to a group of specific connections each between a system channel of the plurality of system channels and a coil channel of the plurality of coil channels of the MRI scanner. Conventionally, for each connection mode between system channels and coil channels of an MRI scanner, at least one MRI scan needs to be performed to calibrate relationships between RF signals of RF channels corresponding to the connection mode. In order to simplify the calibration, a fixed connection mode between the system channels and the coil channels is usually adopted, so as to avoid re-calibrations due to a change in the connection mode involved in an MRI scan. However, such simplification associated with a fixed connection mode may be achieved at the cost of the applicability and/or versatility associated with a detachable RF coil assembly. Moreover, the conventional approach for calibrating relationships between RF signals can only provide a relationship between the RF signals of the RF channels, but cannot provide a relationship between the RF signals (i.e., RF waveforms) of the system channels and a relationship between the RF signals (i.e., RF excitation pulses) of the coil channels. That is, the conventional approach for calibrating relationships between RF signals cannot separate calibration information for the system channels and calibration information for the coil channels.

Another aspect of the present disclosure relates to systems and methods for calibrating relationships between RF signals of channels for transmitting RF signals. The systems may obtain a plurality of sets of image data each of which is acquired by performing an MRI scan using an MRI scanner. The MRI scanner may include a plurality of system channels and a plurality of coil channels. A coil channel may correspond to an RF coil of a plurality of RF coils of an RF coil assembly of the MRI scanner. A system channel of the plurality of system channels may be capable of being operably connected with any one coil channel of the plurality of coil channels of the RF coil assembly of the MRI scanner to form one of a plurality of RF channels of the MRI scanner. The systems may determine, based on the plurality of sets of image data, at least one of a first relationship between RF waveforms of the plurality of system channels and a second relationship between RF excitation pulses of the plurality of coil channels. The first relationship and the second relationship may be configured to provide a plurality of RF parameters for an MRI scan using the MRI scanner in which a specific combination mode of the system channels and coil channels is involved. Compared with the conventional approach for calibrating relationships between RF signals, the systems and methods of the present disclosure may determine the first relationship between the plurality of system channels and the second relationship between the plurality of coil channels, and further the third relationship between the plurality of RF channels may be determined based on the first relationship and the second relationship, which may achieve the calibration of relationships between RF channels corresponding to all connection modes by performing only one calibration, thereby improving the applicability of the detachable RF coil assembly and/or taking advantage of the versatility achievable by the detachable RF coil assembly.

FIG. 1 is a schematic diagram illustrating an exemplary magnetic resonance imaging (MRI) system 100 according to some embodiments of the present disclosure. As illustrated, the MRI system 100 may include an MRI scanner 110 (also referred to as an MR scanner 110), a processing device 120, a storage device 130, one or more terminals 140, and a network 150. The components in the MRI system 100 may be connected in one or more of various ways. Merely by way of example, as illustrated in FIG. 1, the MRI scanner 110 may be connected to the processing device 120 through the network 150. As another example, the MRI scanner 110 may be connected with the processing device 120 directly as indicated by the bi-directional arrow in dotted lines linking the MRI scanner and the processing device 120. As a further example, the storage device 130 may be connected with the processing device 120 directly (not shown in FIG. 1) or through the network 150. As still a further example, a terminal 140 may be connected with the processing device 120 directly (as indicated by the bi-directional arrow in dotted lines linking the terminal 140 and the processing device 120) or through the network 150.

The MRI scanner 110 may scan a (part of) subject or locate within its detection region and generate MR signals relating to the (part of) subject. In the present disclosure, the terms “subject” and “object” are used interchangeably. Merely by way of example, the object may include a patient, a man-made object, etc. As another example, the object may include a specific portion, organ, and/or tissue of a patient. For example, the object may include head, brain, neck, body, shoulder, arm, thorax, cardiac, stomach, blood vessel, soft tissue, knee, feet, or the like, or any combination thereof. In some embodiments, the MRI scanner 110 may be a close-bore scanner or an open-bore scanner.

In the present disclosure, the X axis, the Y axis, and the Z axis shown in FIG. 1 may form an orthogonal coordinate system. The X axis and the Z axis shown in FIG. 1 may be horizontal, and the Y axis may be vertical. As illustrated, the positive x-direction along the X axis may be from the right side to the left side of the MRI scanner 110 seen from the direction facing the front of the MRI scanner 110; the positive y-direction along the Y axis shown in FIG. 1 may be from the lower part to the upper part of the MRI scanner 110; the positive z-direction along the Z axis shown in FIG. 1 may refer to a direction in which the object is moved out of the detection region (or referred to as the bore) of the MRI scanner 110.

The MRI scanner 110 may include a magnet assembly, a gradient coil assembly, a radiofrequency (RF) coil assembly, and an RF generator.

The magnet assembly may generate a first magnetic field (also referred to as a main magnetic field) that may be applied to a subject positioned inside the first magnetic field. The magnet assembly may include a permanent magnet, a superconducting electromagnet, a resistive electromagnet, etc. The magnet assembly may form the detection region and surround, along the z-direction, the object that is moved into or positioned within the detection region.

The gradient coil assembly may be located inside the magnet assembly. For example, the gradient coil assembly may be located in the detection region. The gradient coil assembly may surround, along the z-direction, the subject that is moved into or positioned within the detection region. The gradient coil assembly may be surrounded by the magnet assembly around the z-direction, and be closer to the subject than the magnet assembly. The gradient coil assembly may generate a second magnetic field (also referred to as a gradient field). The second magnetic field may be superimposed on the main magnetic field generated by the magnet assembly and distort the main magnetic field so that the magnetic orientations of the protons of an object may vary as a function of their positions inside the gradient field, thereby encoding spatial information into MR signals generated by the region of the subject being imaged.

The RF generator may be configured to generate RF waveforms for an MRI scan of a subject using the MRI scanner 110. The RF waveforms may be applied to the RF coil assembly to generate RF excitation pulses.

The RF coil assembly may include one or more RF coils. The RF coils may include one or more RF transmit coils and/or one or more RF receiver coils. The RF transmit coil(s) may generate RF excitation pulses by applying the RF waveforms generated by the RF generator to the RF transmit coil(s). The RF excitation pulses may provide a third magnetic field that is utilized to generate MR signals relating to the subject being imaged. The third magnetic field may be perpendicular to the main magnetic field.

Under a coordinated action of the main magnetic field, the gradient magnetic field, and the RF excitation pulses, MR signals relating to the subject may be generated. The RF receiver coils may acquire MR signals from the subject. The MR signals may also be referred to as echo signals. The MR signals may be used to fill a k-space based on a sampling technique. Exemplary sampling techniques may include a Cartesian sampling technique, a spiral sampling technique, a radial sampling technique, a Z-sampling technique, an undersampling technique, etc. The received MR signal(s) may be sent to a processing device (e.g., the processing device 120) directly or via the network 150 for image reconstruction and/or image data processing.

In some embodiments, a part of the MRI system 100 for generating RF signals may be also referred to as an RF transmit system, which may include the RF generator and the RF coil assembly.

The processing device 120 may process data and/or information obtained from the MRI scanner 110, the terminal(s) 140, and/or the storage device 130. For example, the processing device 120 may obtain a plurality of RF parameters for an MRI scan of a subject using the MRI scanner 110. The plurality of RF parameters may include at least one RF parameter of an RF waveform to be transmitted into each of a plurality of system channels of the MRI scanner 110. The processing device 120 may determine a first power loss and a first current square factor of the RF coil assembly under an unloaded condition of the MRI scanner based on the plurality of RF parameters. The processing device 120 may also determine a total power loss of the MRI scan and a second current square factor of the RF coil assembly during the MRI scan based on the plurality of RF parameters. The processing device 120 may also determine a second power loss of the RF coil assembly based on the first power loss, the first current square factor, and the second current square factor. The processing device 120 may further determine a specific absorption ratio (SAR) of the subject during the MRI scan based on the total power loss and the second power loss. As another example, in some embodiments, each system channel of the plurality of system channels of the MRI scanner 110 may be capable of being operably connected with any one coil channel of the plurality of coil channels of the RF coil assembly of the MRI scanner 110 to form one of a plurality of RF channels of the MRI scanner 110. The processing device 120 may obtain a plurality of sets of image data each of which is acquired by performing an MRI scan using the MRI scanner 110. The processing device 120 may further determine a first relationship between RF waveforms of the plurality of system channels and a second relationship between RF excitation pulses of the plurality of coil channels based on the plurality of sets of image data. The first relationship and the second relationship may be configured to provide a plurality of RF parameters for an MRI scan using the MRI scanner 110.

In some embodiments, the processing device 120 may be a single server or a server group. The server group may be centralized or distributed. In some embodiments, the processing device 120 may be local or remote. In some embodiments, the processing device 120 may be implemented on a computing device.

The storage device 130 may store data and/or instructions. In some embodiments, the storage device 130 may store data obtained from the terminal 140 and/or the processing device 120. For example, the storage device 130 may store the first relationship and the second relationship configured to provide a plurality of RF parameters for an MRI scan using the MRI scanner 110. In some embodiments, the storage device 130 may store data and/or instructions that the processing device 120 may execute or use to perform exemplary methods described in the present disclosure. In some embodiments, the storage device 130 may include a mass storage device, a removable storage device, a volatile read-and-write memory, a read-only memory (ROM), or the like, or any combination thereof.

The terminal 140 may include a mobile device 140-1, a tablet computer 140-2, a laptop computer 140-3, or the like, or any combination thereof. In some embodiments, the terminal 140 may remotely operate the MRI scanner 110. In some embodiments, the terminal 140 may receive information and/or instructions inputted by a user, and send the received information and/or instructions to the MRI scanner 110 or the processing device 120 via the network 150. In some embodiments, the terminal 140 may receive data and/or information from the processing device 120. In some embodiments, the terminal 140 may be part of the processing device 120. In some embodiments, the terminal 140 may be omitted.

The network 150 may include any suitable network that can facilitate the exchange of information and/or data for the MRI system 100. In some embodiments, one or more components of the MRI system 100 (e.g., the MRI scanner 110, the terminal 140, the processing device 120, or the storage device 130) may communicate information and/or data with one or more other components of the MRI system 100 via the network 150. For example, the processing device 120 may obtain MR signals from the MRI scanner 110 via the network 150. As another example, the processing device 120 may obtain user instructions from the terminal 140 via the network 150. In some embodiments, the network 150 may be any type of wired or wireless network, or a combination thereof. The network 150 may include any suitable network that can facilitate the exchange of information and/or data for the MRI system 100. In some embodiments, one or more components of the MRI system 100 (e.g., the MRI scanner 110, the terminal 140, the processing device 120, the storage device 130, etc.) may transmit or receive information and/or data with one or more other components of the MRI system 100 via the network 150.

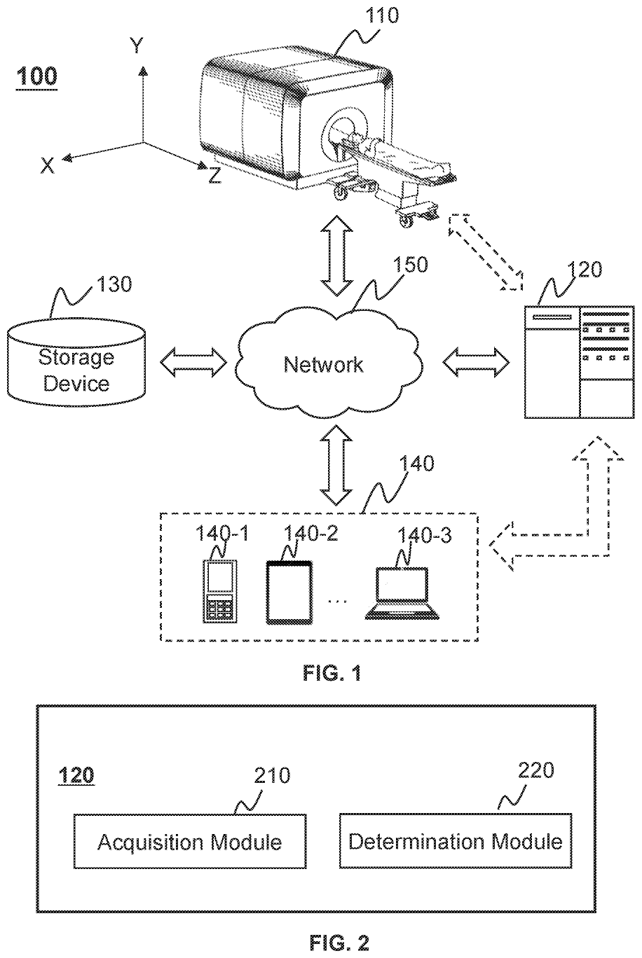

FIG. 2 is a block diagram illustrating an exemplary processing device 120 according to some embodiments of the present disclosure. In some embodiments, the processing device 120 may be implemented on a processing unit. As shown in FIG. 2, the processing device 120 may include an acquisition module 210 and a determination module 220.

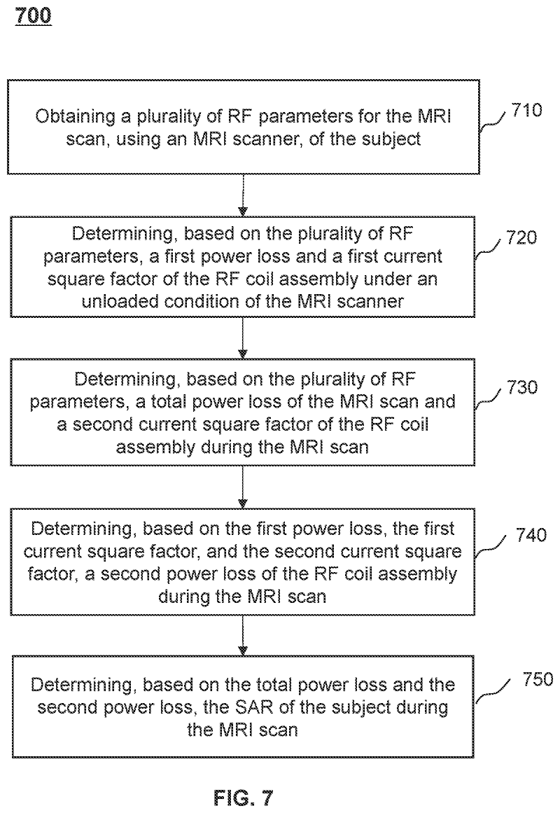

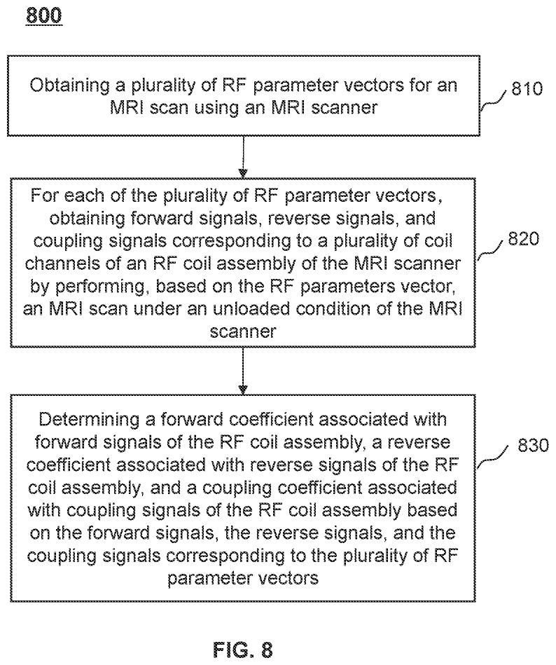

The acquisition module 210 may be configured to obtain information relating to the MRI 100. For example, the acquisition module 210 may obtain a plurality of RF parameters for the MRI scan, using an MRI scanner, of the subject. More descriptions regarding the obtaining of the plurality of RF parameters for the MRI scan, using an MRI scanner, of the subject may be found elsewhere in the present disclosure. See, e.g., operation 710 in FIG. 7, and relevant descriptions thereof. As another example, the acquisition module 210 may obtain a plurality of RF parameter vectors for an MRI scan using an MRI scanner. More descriptions regarding the obtaining of the plurality of RF parameter vectors may be found elsewhere in the present disclosure. See, e.g., operation 810 in FIG. 8, and relevant descriptions thereof. As still another example, the acquisition module 210 may obtain forward signals, reverse signals, and coupling signals corresponding to a plurality of coil channels of an RF coil assembly of the MRI scanner that are acquired by performing, based on the RF parameter vector, an MRI scan under an unloaded condition of the MRI scanner. More descriptions regarding the obtaining of the forward signals, reverse signals, and coupling signals may be found elsewhere in the present disclosure. See, e.g., operation 820 in FIG. 8, and relevant descriptions thereof. As still another example, the acquisition module 210 may obtain a plurality of sets of image data. More descriptions regarding the obtaining of the plurality of sets of image data may be found elsewhere in the present disclosure. See, e.g., operation 1010 in FIG. 10, and relevant descriptions thereof. As still another example, the acquisition module 210 may obtain a plurality of initial RF parameters for the MRI scan, using an MRI scanner, of the subject. More descriptions regarding the obtaining of the plurality of initial RF parameters for the MRI scan, using an MRI scanner, of the subject may be found elsewhere in the present disclosure. See, e.g., operation 1310 in FIG. 13, and relevant descriptions thereof. As still another example, the acquisition module 210 may obtain a first relationship between RF waveforms of the plurality of system channels and a second relationship between RF excitation pulses of the plurality of coil channels. More descriptions regarding the obtaining of the first relationship between RF waveforms of the plurality of system channels and the second relationship between RF excitation pulses of the plurality of coil channels may be found elsewhere in the present disclosure. See, e.g., operation 1320 in FIG. 13, and relevant descriptions thereof.

The determination module 220 may be configured to determine a first power loss and a first current square factor of the RF coil assembly under an unloaded condition of the MRI scanner based on the plurality of RF parameters. The determination module 220 may be also configured to determine a total power loss of the MRI scan and a second current square factor of the RF coil assembly during the MRI scan based on the plurality of RF parameters. The determination module 220 may be also configured to determine a second power loss of the RF coil assembly during the MRI scan based on the first power loss, the first current square factor, and the second current square factor. The determination module 220 may be also configured to determine the SAR of the subject during the MRI scan based on the total power loss and the second power loss. More descriptions regarding the determination of the first power loss, the first current square factor, the total power loss of the MRI scan, the second current square factor, the second power loss, and the SAR of the subject during the MRI scan may be found elsewhere in the present disclosure. See, e.g., operations 720-750 in FIG. 7, and relevant descriptions thereof.

In some embodiments, the determination module 220 may be configured to determine a forward coefficient associated with forward signals of the RF coil assembly, a reverse coefficient associated with reverse signals of the RF coil assembly, and a coupling coefficient associated with coupling signals of the RF coil assembly based on the forward signals, the reverse signals, and the coupling signals corresponding to the plurality of RF parameter vectors. More descriptions regarding the determination of the forward coefficient associated, the reverse coefficient, and the coupling coefficient may be found elsewhere in the present disclosure. See, e.g., operation 830 in FIG. 8, and relevant descriptions thereof.

In some embodiments, the determination module 220 may be configured to determine at least one of a first relationship between RF waveforms of the plurality of system channels and a second relationship between RF excitation pulses of the plurality of coil channels based on the plurality of sets of image data. The first relationship and the second relationship may be configured to provide a plurality of RF parameters for an MRI scan using the MRI scanner. More descriptions regarding the determination of the first relationship and the second relationship may be found elsewhere in the present disclosure. See, e.g., operation 1020 in FIG. 10, and relevant descriptions thereof.

In some embodiments, the determination module 220 may be configured to determine a plurality of target RF parameters for the MRI scan based on the plurality of initial RF parameters, the first relationship, and the second relationship. More descriptions regarding the determination of the plurality of target RF parameters for the MRI scan based on the plurality of initial RF parameters, the first relationship, and the second relationship may be found elsewhere in the present disclosure. See, e.g., operation 1330 in FIG. 13, and relevant descriptions thereof.

It should be noted that the above description is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, the processing device 120 may further include a storage module (not shown in FIG. 2). The storage module may be configured to store data generated during any process performed by any component of the processing device 120. As another example, each of at least some components of the processing device 120 may include a storage apparatus. Additionally or alternatively, at least some components of the processing device 120 may share a common storage apparatus.

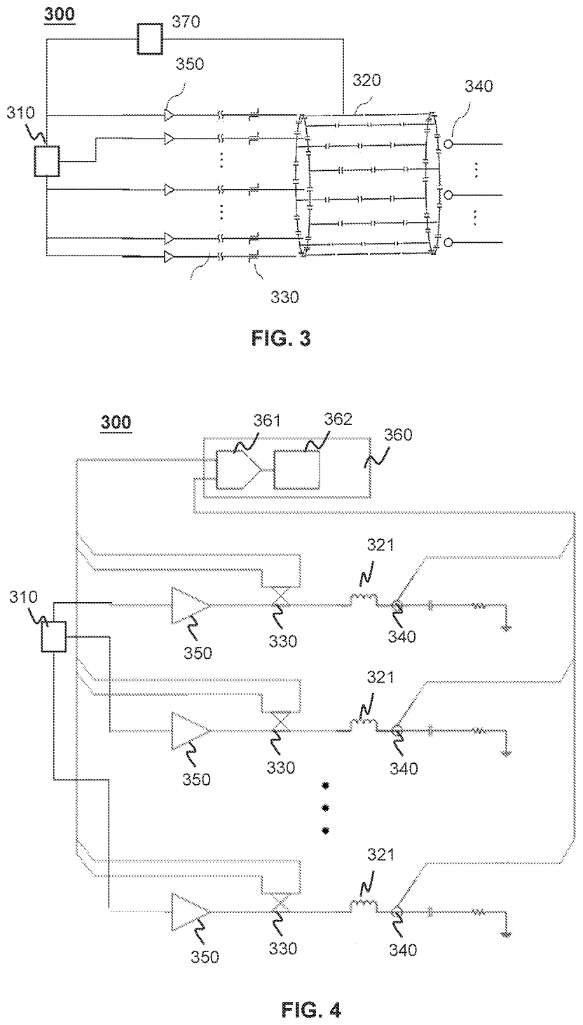

FIG. 3 and FIG. 4 are schematics illustrating an exemplary RF transmit system 300 of an MRI system according to some embodiments of the present disclosure. In some embodiments, the RF transmit system 300 may be an exemplary embodiment of a part of the MRI system 100 for generating RF signals (i.e., the RF waveforms and the RF excitation pulses) described in FIG. 1.

As shown in FIG. 3 and FIG. 4, the RF transmit system 300 may include an RF generator 310, an RF coil assembly 320, a plurality of directional couplers 330, and a plurality of coupling probes 340.

The RF generator 310 may be configured to generate RF waveforms (e.g., RF pulses waveforms). The RF waveforms may be generated based on a plurality of RF parameters. In some embodiments, the RF generator 310 may include a plurality of system channels for transmitting the RF waveforms. In some embodiments, a system channel may be controlled by an RF controller independently to transmit a RF waveform. In some embodiments, one or more system channels, but not all, of the plurality of system channels may each transmit a RF waveform during an MRI scan. Alternatively, a plurality of system channels may be simultaneously controlled by the RF controller to simultaneously transmit RF waveforms corresponding to the plurality of system channels. In some embodiments, the plurality of RF parameters may include at least one RF parameter of a RF waveform to be transmitted into each of the plurality of system channels. At least one RF parameter of a RF waveform may include an amplitude value, a phase value, etc., of the RF waveform.

The RF coil assembly 320 may be configured to generate RF excitation pulses by applying the RF waveforms to the RF coil assembly 320 to perform an MRI scan using an MRI scanner. In some embodiments, the RF coil assembly 320 may include a plurality of RF coils (or referred to as coils for brevity) 321. A coil 321 refers to a transmit coil described in FIG. 1. A coil 321 of the plurality of coils 321 may correspond one coil channel of a plurality of coil channels. A coil channel of the plurality of coil channels may be operably connected to one system channel of the plurality of system channels to form one of a plurality of RF channels (also referred to as RF transmission channels) of the MRI scanner. In some embodiments, as shown in FIG. 4, each coil 321 of the RF coil assembly 320 may be operably connected to at least one capacitance and/or at least one inductance to form a coil unit.

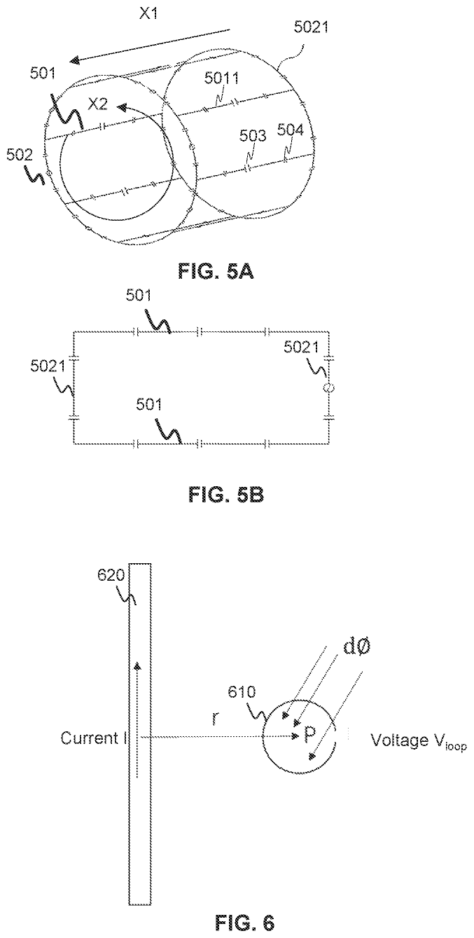

Merely by way of example, FIG. 5A is a schematic illustrating an exemplary RF coil assembly 320 according to some embodiments of the present disclosure. As shown in FIG. 5A, the RF coil assembly 320 may have a cylindrical structure. The RF coil assembly 320 may include a plurality of rung portions 501 with transverse end antennas and two end portions 502 with end loop antennas. The end portions 502 may be located at both ends of the RF coil assembly 320 in an axial direction X1 of the RF coil assembly 320. The plurality of rung portions 501 may be located between and connected to the two end portions 502. Specifically, each end portion may include a plurality of end units 5201, and the plurality of end units 5201 may be arranged along a circumferential direction X2 of the RF coil assembly 320 to form an annular end portion. Both ends of each end unit 5201 may be respectively connected with two rung portions 501. The plurality of rung portions 501 may be arranged at intervals (e.g., evenly spaced) in the circumferential direction X2 of the RF coil assembly 320, and the rung portions 501 may extend along the axial direction X1 of the RF coil assembly 320. In some embodiments, each rung portion 501 may include a plurality of rung units 5011 disposed along the axial direction X1 of the RF coil assembly 320. Each two adjacent rung units 5011 in a rung portion 501 may be operably connected by capacitors. As used herein, two rung units 5011 are considered adjacent if there is no other rung unit 5011 located between the two rung units 5011. In some embodiments, two adjacent rung units 5011 located in the middle of a rung portion 501 may be connected by a fixed capacitance (e.g., a fixed capacitance 503) whose capacitance value may be fixed and not adjustable). Two adjacent rung units 5011 near the end portions 502 may be operably connected through an adjustable capacitor (e.g., a fixed capacitance 504) whose capacitance values may be adjusted. In some embodiments, the rung units 5011 and the end portions 502 may be also connected through adjustable capacitors. In this way, an error of each fixed capacitor may be adjusted by the adjustable capacitors, so as to achieve an accurate transmit frequency calibration.

The RF coil assembly 320 may include multiple coil loops. FIG. 5B provides a schematic illustrating an exemplary coil loop according to some embodiments of the present disclosure. As shown in FIG. 5B, two adjacent rung portions 501 and two end units 5021 operably connected with the two rung portions may form a coil loop. Accordingly, the RF coil assembly 320 may include a plurality of coil loops arranged in the circumferential direction of the RF coil assembly 320. In some embodiments, a count of the coil loops may be equal to a count of the rung portions.

The plurality of directional couplers 330 may be configured to collect forward signals and/or reverse signals of the RF coil assembly 320 during the MRI scan. Each of the plurality of directional couplers 330 may be arranged between the RF generator 310 and one coil 321 of the plurality of coils 321 and configured to collect a forward signal and/or a reverse signal of the coil 321 during the MRI scan. That is, each directional coupler 330 may be operably connected with one system channel of the RF generator 310 and one coil channel corresponding to the system channel and configured to collect a forward signal and/or a reverse signal of the coil channel during the MRI scan.

The plurality of coupling probes 340 may be configured to collect coupling signals of the RF coil assembly 320 during the MRI scan. In some embodiments, each of the plurality of coupling probes 340 may be arranged near one coil 321 of the plurality of coils 321 and configured to collect a coupling signal of the coil 321 during the MRI scan. In some embodiments, a coupling probe 340 may be arranged within a near-field radiation range of the coil 321 corresponding to the coupling probe 340. In some embodiments, the coupling signal may be a current signal. Merely by way of example, if an RF current passing a conductor is I, according to Bio-Savart's law, a magnetic field B generated at a point near the conductor may satisfy a relation:

$$dB = \frac{{μ}_{0} Idl \times r}{4 π {r}^{3}} ,$$

wherein, μₒ denotes the vacuum permeability, dl denotes a tiny line element of the RF current I, and r denotes a distance between the conductor and the point. It can be seen from this that the magnetic field B generated by the RF current I at point P is proportional to the RF current I and inversely proportional to a square of the distance r. FIG. 6 illustrates a measurement of a current signal of a coil using a coupling probe according to some embodiments of the present disclosure. As shown in FIG. 6, a coupling probe 610 with a current probe coupling loop may be arranged at a point P near a coil loop 620 of a coil 321 of the RF coil assembly 320, and an area of the current probe coupling loop is A, then a voltage Vₗₒₒₚ induced by the current probe coupling loop and a magnetic flux d∅ of the current probe coupling loop may satisfy a relation: Vₗₒₒₚ=−d∅/dt. Assuming that the magnetic field B is uniform within the range of area A, the voltage coupled by the current probe coupling loop may be Vₗₒₒₚ=A*(dB/dt), and so the voltage Vₗₒₒₚ coupled by the current probe coupling loop may be proportional to the RF current I. Therefore, the RF current/of the coil loop can be obtained by performing a mathematical transform on coupling data (e.g., voltage Vₗₒₒₚ) of the current probe coupling loop.

In some embodiments, the RF transmit system 300 may include a plurality of RF power amplifiers (RFPAs) 350 operably connected to the RF generator 310. The plurality of RFPAs 350 may be configured to receive and amplify the RF waveforms (e.g., the powers of the RF waveforms, the voltages of the RF waveforms) and transmit the amplified RF waveforms to the RF coil assembly 320 such that the RF coil assembly 320 is driven to generate the RF excitation pulses. Specifically, each of the plurality of RFPAs 350 may be operably connected with one system channel of the RF generator 310, and configured to receive and amplify the RF waveform of the system channel and transmit the amplified RF waveform to one coil channel operably connected with or otherwise corresponding to the system channel. In some embodiments, each of the plurality of RFPAs 350 may be arranged between the RF generator 310 and one of the plurality of directional couplers 330. Exemplary RFPAs may include a transistor-based RFPA, a vacuum tube-based RFPA, or the like, or any combination thereof. The transistor-based RFPA may include one or more transistors. The vacuum tube-based RFPA may include a triode, a tetrode, a klystron, or the like, or any combination thereof. In some embodiments, the RFPAs 350 may include linear RFPAs and/or nonlinear RFPAs.

In some embodiments, as shown in FIG. 4, the RF transmit system 300 may include a processing device 360 (not shown in FIG. 3). In some embodiments, the processing device 360 may be the processing device 120 as described in connection with FIG. 1. The processing device 360 may be configured to determine a power loss of the RF coil assembly 320 during the MRI scan based on the forward signals, the reverse signals, and the coupling signals of the RF coil assembly 320. The processing device 360 may include an analog-to-digital converter (ADC) 361 and/or a data processing unit 362. A forward coupling end and a reverse coupling end of each directional coupler 330, and each coupling probe 340 may be operably connected to the ADC 361 by a wired or wireless connection to transmit the forward signals, the reverse signals, and the coupling signals to the ADC 361. The ADC 361 may be configured to generate forward data, reverse data, and coupling data of the RF coil assembly 320 by performing analog-to-digital conversions on the forward signals, the reverse signals, and the coupling signals of the RF coil assembly 320, respectively. The ADC 361 may perform analog-to-digital conversions on received forward signals, the reverse signals, and the coupling signals of the RF coil assembly 320 to convert the forward signals, the reverse signals, and the coupling signals from analog signals to digital signals, respectively. Further, the ADC 361 may perform quadrature demodulations on the digital signals to obtain the forward data, the reverse data, and the coupling data of the RF coil assembly 320. The forward data, the reverse data, and the coupling data may include amplitude information and phase information. Exemplary ADCs 361 may include a direct-conversion ADC, a successive-approximation ADC, a ramp-compare ADC, a Wilkinson ADC, an integrating ADC, a delta-encoded ADC, a pipeline ADC, a sigma-delta ADC, or the like, or a combination thereof. The generated forward data, reverse data, and coupling data of the RF coil assembly 320 may be sent to the data processing unit 362. The data processing unit 362 may be configured to determine the power loss of the RF coil assembly 320 during the MRI scan based on the forward data, reverse data, and coupling data of the RF coil assembly 320. More descriptions for the determination of a power loss of an RF coil assembly during an MRI scan may be found elsewhere in the present disclosure (e.g., FIG. 6 and the descriptions thereof).

In some embodiments, the MRI scan may be performed on a subject, and the data processing device 360 may be configured to determine a specific absorption ratio (SAR) of the subject during the MRI of the subject based on the power loss of the RF coil assembly 320. More descriptions for a determination of an SAR of a subject during an MRI of the subject may be found elsewhere in the present disclosure (e.g., FIG. 7 and the descriptions thereof).

In some embodiments, the RF transmit system 300 may include a controller 370. In some embodiments, the controller 370 may be configured to control resonance or detuning of the RF coil assembly 320 according to the SAR of the subject. In some embodiments, the controller 370 may be configured to adjust the plurality of RF parameters (e.g., amplitude values, phase values, etc.) for the MRI scan according to the SAR of the subject. For example, in response to determining that the SAR of the subject exceeds an SRA preset, the processing unit 362 may send prompt information to the controller. The controller 370 may control resonance or detuning of the RF coil assembly 320, or adjust the plurality of RF parameters for the MRI scan according to the SAR of the subject. In some embodiments, the controller 370 may also issue an alarm to prompt a user. In this way, the safety of the subject during the MRI scan may be ensured, thereby realizing the monitoring of the RF safety of the RF transmit system 300.

FIG. 7 is a flowchart illustrating an exemplary process 700 for determining an SAR of a subject during an MRI scan of the subject according to some embodiments of the present disclosure. In some embodiments, the process 700 may be implemented in the MRI system 100 illustrated in FIG. 1. For example, the process 700 may be stored in a storage (e.g., the storage device 130) as a form of instructions, and invoked and/or executed by the processing device 120 (e.g., one or more modules as illustrated in FIG. 2). The operations of the illustrated process presented below are intended to be illustrative. In some embodiments, the process 700 may be accomplished with one or more additional operations not described, and/or without one or more of the operations discussed. Additionally, the order in which the operations of the process 700 as illustrated in FIG. 7 and described below is not intended to be limiting.

As used herein, the subject may include a biological subject and/or a non-biological subject. For example, the subject may be a human being, an animal, or a portion thereof. As another example, the subject may be a phantom. In some embodiments, the subject may be a patient, or a portion of the patient (e.g., the chest, a breast, and/or the abdomen of the patient).

In 710, the processing device 120 (e.g., the acquisition module 210) may obtain a plurality of RF parameters for the MRI scan, using an MRI scanner, of the subject.

In some embodiments, the MR scanner may be the MR scanner 110 described in connection with FIG. 1. An RF transmit system for generating RF signals of the MR scanner may be the RF transmit system 300. The plurality of RF parameters may include at least one RF parameter of an RF waveform to be transmitted into each of a plurality of system channels of the MR scanner. Each of the plurality of system channels may be connected to one of a plurality of coil channels of an RF coil assembly of the MRI scanner to form a RF channel. The MRI scanner may include a plurality of RF channels. In some embodiments, at least one RF parameter of an RF waveform to be transmitted into a system channel may include an amplitude value and a phase value of the RF waveform to be transmitted into the system channel.

In some embodiments, the processing device 120 may obtain the plurality of RF parameters for the MRI scan from the MRI scanner. In some embodiments, the plurality of RF parameters for the MRI scan may be previously generated and stored in a storage device (e.g., the storage device 130 or an external source). The processing device 120 may retrieve the plurality of RF parameters directly from the storage device.

In 720, the processing device 120 (e.g., the determination module 220) may determine, based on the plurality of RF parameters, a first power loss and a first current square factor of the RF coil assembly under an unloaded condition of the MRI scanner.

As used herein, the first power loss and the first current square factor of the RF coil assembly under an unloaded condition of the MRI scanner refer to a power loss and a current square factor of the RF coil assembly during a calibration MRI scan performed, based on the plurality of RF parameters, on the air or a phantom with a low RF energy absorption rate. The calibration MRI scan may be performed when the subject to be imaged is not positioned in the MRI scanner.

In some embodiments, the processing device 120 may obtain a first forward coefficient associated with forward signals of the RF coil assembly, a first reverse coefficient associated with reverse signals of the RF coil assembly, and a first coupling coefficient associated with coupling signals of the RF coil assembly. In some embodiments, the processing device 120 may obtain, from the MRI scanner, the plurality of RF parameters for the MRI scan. In some embodiments, the first forward coefficient, the first reverse coefficient, and the first coupling coefficient may be previously generated (e.g., during the installation or maintenance of the MRI scanner) and stored in a storage device (e.g., the storage device 130 or an external source). The processing device 120 may retrieve the first forward coefficient, the first reverse coefficient, and the first coupling coefficient directly from the storage device. More descriptions for the determining of the first forward coefficient, the first reverse coefficient, and the first coupling coefficient may be found elsewhere in the present disclosure (e.g., FIG. 8 and the descriptions thereof).

The processing device 120 may determine the first power loss and the first current square factor based on the RF parameters, the first forward coefficient, the first reverse coefficient, and the first coupling coefficient. As used herein, a current square factor may relate to a current of each coil of the RF coil assembly.

In some embodiments, the processing device 120 may determine forward dada, reverse dada, and coupling data corresponding to the coil channel of each RF channel under the unloaded condition of the MRI scanner based on the RF parameters, the first forward coefficient, the first reverse coefficient, and the first coupling coefficient. Further, the first power loss and the first current square factor may be determined based on the forward dada, the reverse dada, and the coupling data corresponding to the coil channel of each RF channel under the unloaded condition of the MRI scanner. More descriptions for the obtaining of the forward dada, the reverse dada, and the coupling data may be found elsewhere in the present disclosure (e.g., FIG. 3 and the descriptions thereof).

In some embodiments, the forward dada and reverse dada corresponding to a coil channel may be a forward voltage and a reverse voltage corresponding to the coil channel, respectively. The coupling data corresponding to a coil channel may be a current corresponding to the coil channel. Merely by way of example, the processing device 120 may determine a forward voltage, a reverse voltage, and a current corresponding to the coil channel of each RF channel under the unloaded condition of the MRI scanner based on the RF parameters, the first forward coefficient, the first reverse coefficient, and the first coupling coefficient according to Equation (1) to Equation (3) as below:

[UF_{unload_1}, . . . , UF_{unload}_{ᵢ}, . . . , UF_{unload_n}]^{H}=M1*[A₁(∅₁), . . . , Aᵢ(∅ᵢ, . . . , Aₙ(∅ₙ)]^{H}, (1)

[UR_{unload_1}, . . . , UR_{unload}_{ᵢ}, . . . , UR_{unload_n}]^{H}=M2*[A₁(∅₁), . . . , Aᵢ(∅ᵢ, . . . , Aₙ(∅ₙ)]^{H} (2)

[I_{unload_1}, . . . , I_{unload}_{ᵢ}, . . . , I_{unload_n}]^{H}=M3*[A₁(∅₁), . . . , Aᵢ(∅ᵢ), . . . , Aₙ(∅ₙ)]^{H} (3)

where n denotes a count of the plurality of RF channels, i denotes the ith RF channel, Aᵢ(∅ᵢ) denotes an amplitude value Aᵢ and a phase value ∅ᵢ of an RF waveform to be transmitted into the system channel of the ith RF channel, UF_{unload}_{ᵢ} denotes a forward voltage corresponding to the coil channel of the ith RF channel under the unloaded condition of the MRI scanner, UR_{unload}_{ᵢ} denotes a reverse voltage corresponding to the coil channel of the ith RF channel under the unloaded condition of the MRI scanner, I_{unload_i} denotes a current corresponding to the coil channel of the ith RF channel under the unloaded condition of the MRI scanner, the superscript H denotes a transpose of a vector, M1 denotes the first forward coefficient, M2 denotes the first reverse coefficient, and M3 denotes the first coupling coefficient.

Further, the first power loss and the first current square factor may be determined according to Equation (4) and Equation (5) as below:

$$\begin{matrix}{Coil\_loss}_{unload} = {\sum }_{i = 1}^{n} ( {\vert \frac{{UF}_{unload \_ i}}{Z 0} \vert}^{2} - {\vert \frac{{UR}_{unload \_ i}}{Z 0} \vert}^{2} ) , & ( 4 ) \\ {I}_{unload}^{2} = {\sum }_{i = 1}^{n} {\vert {I}_{unload \_ i} \vert}^{2} , & ( 5 )\end{matrix}$$

where Coil_loss_{unload} denotes the first power loss, I_{unload}² denotes the current square factor as an exemplary first current square factor, ZO denotes a characteristic impedance of the RF transmit system.

In 730, the processing device 120 (e.g., the determination module 220) may determine, based on the plurality of RF parameters, a total power loss of the MRI scan and a second current square factor of the RF coil assembly during the MRI scan.

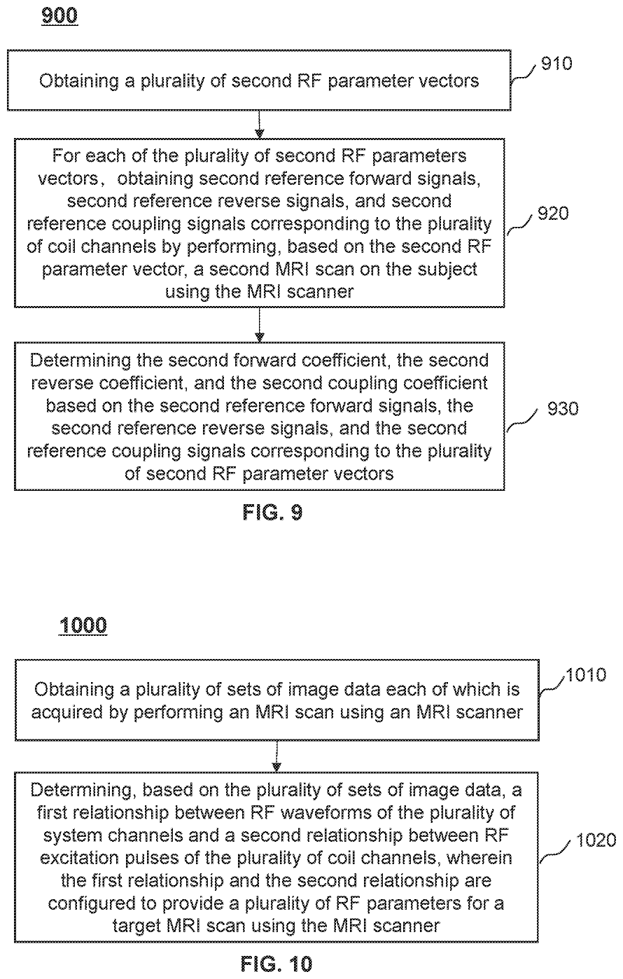

In some embodiments, the processing device 120 may determine a second forward coefficient associated with forward signals of the RF coil assembly, a second reverse coefficient associated with reverse signals of the RF coil assembly, and a second coupling coefficient associated with coupling signals of the RF coil assembly. More descriptions for the determination of the second forward coefficient, the second reverse coefficient, and the second coupling coefficient may be found elsewhere in the present disclosure (e.g., FIG. 9 and the descriptions thereof). The processing device 120 may determine the total power loss of the MRI scan and the second current square factor of the RF coil assembly based on the plurality of RF parameters, the second forward coefficient, the second reverse coefficient, and the second coupling coefficient.

In some embodiments, the processing device 120 may determine forward dada, reverse dada, and coupling data corresponding to the coil channel of each RF channel during the MRI scan based on the RF parameters, the second forward coefficient, the second reverse coefficient, and the second coupling coefficient. Merely by way of example, the processing device 120 may determine a forward voltage, a reverse voltage, and a current corresponding to the coil channel of each RF channel during the MRI based on the RF parameters, the second forward coefficient, the second reverse coefficient, and the second coupling coefficient according to Equation (6) to Equation (8) as below:

[UF_{load_1}, . . . , UF_{load}_{ᵢ}, . . . , UF_{load_n}]^{H}=M4*[A₁(∅₁), . . . , A₂(∅₂), . . . , Aₙ(∅ₙ)]^{H} (6)

[UR_{load_1}, . . . , UR_{load}_{ᵢ}, . . . , UR_{load_n}]^{H}=M5*[A₁(∅₁), . . . , A₂(∅₂), . . . , Aₙ(∅ₙ)]^{H} (7)

[I_{load_1}, . . . , I_{load}_{ᵢ}, . . . , I_{load_n}]^{H}=M6*[A₁(∅₁), . . . , A₂(∅₂) , . . . , Aₙ(∅ₙ)]^{H} (8)

Where UF_{load}_{ᵢ} denotes a forward voltage corresponding to the coil channel of the ith RF channel during the MRI scan, UR_{unload}_{ᵢ} denotes a reverse voltage corresponding to the coil channel of the ith RF channel during the MRI scan, I_{unload_i} denotes a current corresponding to the coil channel of the ith RF channel during the MRI scan, M4 denotes the second forward coefficient, M5 denotes the second reverse coefficient, and M6 denotes the second coupling coefficient.

In some embodiments, the processing device 120 may determine whether the plurality of RF parameters satisfy a preset condition. In some embodiments, the preset condition may include that a ratio between the amplitude values of the system channel and the coil channel of each RF channel of the plurality of RF channels is the same among the plurality of RF channels during the MRI scan, and that a difference between phase values of the system channel and the coil channel of each RF channel of the plurality of system channels is the same among the plurality of RF channels during the MRI scan. For instance, for RF channel 1, RF channel 2, . . . , RF channel m, the ratio between the amplitude values of the system channel and the coil channel of each RF channel is the same during the MRI scan. As another example, for RF channel 1, RF channel 2, . . . , RF channel m, the difference between the phase values of the system channel and the coil channel of each RF channel is the same during the MRI scan. As used herein, an amplitude value and a phase value of a system channel refers to an amplitude value and a phase value of the RF waveform of the system channel. In response to determining that the plurality of RF parameters satisfy the preset condition, the processing device 120 may obtain forward signals, reverse signals, and coupling signals corresponding to the plurality of coil channels collected during the MRI scan of the subject. As described in FIG. 3, the forward signals, the reverse signals, and the coupling signals collected during the MRI scan of the subject may be subject to analog-to-digital conversions and/or quadrature demodulations to provide actual forward data, actual reverse data, and actual coupling data, and the obtained actual forward data, actual reverse data, and actual coupling data may be directly designated as the forward data, the reverse data, and the coupling data corresponding to the coil channels during the MRI scan.

Further, the total power loss and the second current square factor may be determined based on the forward dada, the reverse dada, and the coupling data corresponding to the coil channel of each RF channel during the MRI scan. For example, the total power loss and the second current square factor may be determined according to Equation (9) and Equation (10) as below:

$$\begin{matrix}{Total\_loss}_{load} = {\sum }_{i = 1}^{n} ( {\vert \frac{{UF}_{load \_ i}}{Z 0} \vert}^{2} - {\vert \frac{{UR}_{load \_ i}}{Z 0} \vert}^{2} ) , & ( 9 ) \\ {I}_{load}^{2} = {\sum }_{i = 1}^{n} {\vert {I}_{load \_ i} \vert}^{2} , & ( 10 )\end{matrix}$$

where Total_loss_{load} denotes the total power loss, and I_{load}² denotes the second current square factor (i.e., the current square factor).

In 740, the processing device 120 (e.g., the determination module 220) may determine, based on the first power loss, the first current square factor, and the second current square factor, a second power loss of the RF coil assembly during the MRI scan.

Merely by way of example, if the current square factor is a current square factor, the processing device 120 may determine the second power loss of the RF coil assembly according to Equation (11) as below:

$${Coil\_loss}_{load} = {Coil\_loss}_{unload} * \frac{{I}_{load}^{2}}{{I}_{unload}^{2}} , \qquad ( 11 )$$

where Coil_loss_{load} denotes the second power loss during the MRI scan.

In 750, the processing device 120 (e.g., the determination module 220) may determine, based on the total power loss and the second power loss, the SAR of the subject during the MRI scan.

In some embodiments, the processing device 120 may determine a power Power_{subject} absorbed by the subject during the MRI scan based on the total power loss and the second power loss according to Equation (12) as below:

Power_{subject}=Total_loss_{load} −Coil_loss_{load}. (12)

Further, the processing device 120 may determine the SAR of the subject during the MRI scan according to Equation (13) as below:

$$SAR = \frac{1}{Mass} {\int }_{0}^{t} {Power}_{subject} ( t ) dt , \qquad ( 13 )$$

where Mass denotes a mass of the subject, t denotes an average time for calculating SAR.

In some embodiments, in response to determining that a value of the SAR of the subject exceeds a threshold, processing device 120 may adjust at least one RF parameter of the plurality of RF parameters, such as amplitude values, phase values, or the like, or a combination thereof, of the RF waveforms to be transmitted into the plurality of system channels.

Compared with a conventional approach for determining an SAR of a subject in which the power loss occurred in the RF coil assembly is also included in the SAR, instead of being separated out, according to some embodiments of the preset disclosure, the power loss of the RF coil assembly during the MRI scan (i.e., the second power loss) may be determined, and the SAR of the subject during the MRI scan may be determined based on the total power loss for the MRI scan and the second power loss of the RF coil assembly, which may provide a more accurate assessment of the SAR of the subject.

FIG. 8 is a flowchart illustrating an exemplary process 800 for determining a forward coefficient, a reverse coefficient, and a coupling coefficient according to some embodiments of the present disclosure. In some embodiments, the process 800 may be implemented in the MRI system 100 illustrated in FIG. 1. For example, the process 800 may be stored in a storage (e.g., the storage device 130) as a form of instructions, and invoked and/or executed by the processing device 120 (e.g., one or more modules as illustrated in FIG. 2). The operations of the illustrated process presented below are intended to be illustrative. In some embodiments, the process 800 may be accomplished with one or more additional operations not described, and/or without one or more of the operations discussed. Additionally, the order in which the operations of the process 800 as illustrated in FIG. 8 and described below is not intended to be limiting.

In 810, the processing device 120 (e.g., the acquisition module 210) may obtain a plurality of RF parameter vectors for an MRI scan using an MRI scanner.

An element of each of the plurality of RF parameter vectors (also referred to as the plurality of first RF parameter vectors) may include RF parameters of an RF waveform to be transmitted int one of a plurality of system channels of the MRI scanner. In some embodiments, the plurality of RF parameter vectors may be linearly independent. In some embodiments, each of the plurality of RF parameter vectors may be represented as a row vector, and the plurality of RF parameter vectors may form a matrix. For example, the plurality of RF parameter vectors may form a diagonal matrix (also referred to a first diagonal matrix). That is, in each of the plurality of RF parameter vectors, only the RF parameters of an RF waveform to be transmitted int one system channel is greater than 0, and the RF parameters of RF waveforms to be transmitted int the remaining system channels in the RF parameter vector are all 0.

In 820, for each of the plurality of RF parameter vectors, the processing device 120 (e.g., the acquisition module 210) may obtain forward signals, reverse signals, and coupling signals corresponding to a plurality of coil channels of an RF coil assembly of the MRI scanner that are acquired by performing, based on the RF parameter vector, an MRI scan (also referred to as a first reference MRI scan) under an unloaded condition of the MRI scanner.

The forward signals may also be referred to as first reference forward signals. The reverse signals may also be referred to as a first reference reverse signals. The coupling signals may also be referred to as first reference coupling signals.

As used herein, that an MRI scan is performed under an unloaded condition of the MRI scanner refers to that the MRI scan is performed on the air or a subject with a low RF energy absorption rate.

Merely by way of example, the plurality of RF parameter vectors may form a diagonal matrix whose elements on the diagonal are all A₀(∅₀), wherein A₀ denotes an amplitude value, and ∅₀ denotes a phase value, that is, the diagonal matrix may be represented as

$$[ \begin{matrix}{A}_{0} ( {∅}_{0} ) & 0 & … & 0 \\ 0 & {A}_{0} ( {∅}_{0} ) & … & 0 \\ … & … . & … & 0 \\ 0 & … . & 0 & {A}_{0} ( {∅}_{0} )\end{matrix} ] ,$$

wherein a row of the diagonal matrix corresponds to an RF parameter vector. If a count of the RF channels is n, n MRI scans may need to be performed based on the diagonal matrix. Each MRI scan of the n MRI scans may be performed by transmitting an RF waveform with an amplitude value A₀ and a phase value ∅₀ via one of the plurality of system channels.

In 830, the processing device 120 (e.g., the determination module 220) may determine a forward coefficient (also referred to as a first forward coefficient) associated with forward signals of the RF coil assembly, a reverse coefficient (also referred to as a first reverse coefficient) associated with reverse signals of the RF coil assembly, and a coupling coefficient (also referred to as a first coupling coefficient) associated with coupling signals of the RF coil assembly based on the forward signals, the reverse signals, and the coupling signals corresponding to the plurality of RF parameter vectors.

As described in FIG. 3, the forward signals, the reverse signals, and the coupling signals may be subject to analog-to-digital conversions and/or quadrature demodulations to provide first forward data, first reverse data, and first coupling data. Merely by way of example, first forward data, first reverse data, and first coupling data obtained by transmitting an RF waveform with an amplitude value A o and a phase value 0 0 via the first system channel may be [UF_{unload_11}, UF_{unload_21},. . . , UF_{unload_n1}], [UR_{unload_11}, UR_{unload_21}, . . . , UR_{unload_n1}], [I_{unload_11}, I_{unload_21}, . . . , I_{unload_n1}], respectively; first forward data, first reverse data, and first coupling data obtained by transmitting an RF waveform with an amplitude value A₀ and a phase value ∅₀ via the second system channel may be [UF_{unload_12}, UF_{unload_22}, . . . , UF_{unload_n2}], [UR_{unload_12}, UR_{unload_22}, . . . , UR_{unload_n2}], [I_{unload_12}, I_{unload_22}, . . . , I_{unload_n2}], respectively; . . . ; first forward data, first reverse data, and first coupling data obtained by transmitting an RF waveform with an amplitude value A₀ and a phase value ∅₀ via the nth system channel may be [UF_{unload_1n}, UF_{unload_2n}, . . . , UF_{unload_nn}], [UR_{unload_1n}, UR_{unload_2n}, . . . , UR_{unload_nn}], [I_{unload_1n}, I_{unload_2n}, . . . , I_{unload_nn}] respectively. The first subscript and second subscript of each of the first forward data, the first reverse data, and the first coupling data denote which coil channel and which system channel are involved for transmitting the RF signal, respectively.

The processing device 120 may determine the forward coefficient, the reverse coefficient, and the coupling coefficient based on the first forward data, the first reverse data, and the first coupling data corresponding to the plurality of RF parameter vectors. For example, the forward coefficient M1 may be represented as

$$[ \begin{matrix}\frac{{UF}_{unload \_ 11}}{{A}_{0} ( {∅}_{0} )} & \frac{{UF}_{unload \_ 12}}{{A}_{0} ( {∅}_{0} )} & \frac{{UF}_{unload \_ 13}}{{A}_{0} ( {∅}_{0} )} & … & \frac{{UF}_{unload \_ 1 n}}{{A}_{0} ( {∅}_{0} )} \\ \frac{{UF}_{unload \_ 12}}{{A}_{0} ( {∅}_{0} )} & \frac{{UF}_{unload \_ 22}}{{A}_{0} ( {∅}_{0} )} & \frac{{UF}_{unload \_ 23}}{{A}_{0} ( {∅}_{0} )} & … & \frac{{UF}_{unload \_ 2 n}}{{A}_{0} ( {∅}_{0} )} \\ \frac{{UF}_{unload \_ 13}}{{A}_{0} ( {∅}_{0} )} & \frac{{UF}_{unload \_ 23}}{{A}_{0} ( {∅}_{0} )} & \frac{{UF}_{unload \_ 33}}{{A}_{0} ( {∅}_{0} )} & … & \frac{{UF}_{unload \_ 3 n}}{{A}_{0} ( {∅}_{0} )} \\ ⋯ & ⋯ & ⋯ & ⋯ & ⋯ \\ \frac{{UF}_{unload \_ n 1}}{{A}_{0} ( {∅}_{0} )} & \frac{{UF}_{unload \_ n 2}}{{A}_{0} ( {∅}_{0} )} & \frac{{UF}_{unload \_ n 3}}{{A}_{0} ( {∅}_{0} )} & … & \frac{{UF}_{unload \_ n n}}{{A}_{0} ( {∅}_{0} )}\end{matrix} ] .$$

The reverse coefficient M2 may be represented as

$$[ \begin{matrix}\frac{{UF}_{unload \_ 11}}{{A}_{0} ( {∅}_{0} )} & \frac{{UF}_{unload \_ 12}}{{A}_{0} ( {∅}_{0} )} & \frac{{UF}_{unload \_ 13}}{{A}_{0} ( {∅}_{0} )} & … & \frac{{UF}_{unload \_ 1 n}}{{A}_{0} ( {∅}_{0} )} \\ \frac{{UF}_{unload \_ 12}}{{A}_{0} ( {∅}_{0} )} & \frac{{UF}_{unload \_ 22}}{{A}_{0} ( {∅}_{0} )} & \frac{{UF}_{unload \_ 23}}{{A}_{0} ( {∅}_{0} )} & … & \frac{{UF}_{unload \_ 2 n}}{{A}_{0} ( {∅}_{0} )} \\ \frac{{UF}_{unload \_ 13}}{{A}_{0} ( {∅}_{0} )} & \frac{{UF}_{unload \_ 23}}{{A}_{0} ( {∅}_{0} )} & \frac{{UF}_{unload \_ 33}}{{A}_{0} ( {∅}_{0} )} & … & \frac{{UF}_{unload \_ 3 n}}{{A}_{0} ( {∅}_{0} )} \\ ⋯ & ⋯ & ⋯ & ⋯ & ⋯ \\ \frac{{UF}_{unload \_ n 1}}{{A}_{0} ( {∅}_{0} )} & \frac{{UF}_{unload \_ n 2}}{{A}_{0} ( {∅}_{0} )} & \frac{{UF}_{unload \_ n 3}}{{A}_{0} ( {∅}_{0} )} & … & \frac{{UF}_{unload \_ n n}}{{A}_{0} ( {∅}_{0} )}\end{matrix} ] .$$

The coupling coefficient M3 may be represented as

$$[ \begin{matrix}\frac{{UF}_{unload \_ 11}}{{A}_{0} ( {∅}_{0} )} & \frac{{UF}_{unload \_ 12}}{{A}_{0} ( {∅}_{0} )} & \frac{{UF}_{unload \_ 13}}{{A}_{0} ( {∅}_{0} )} & … & \frac{{UF}_{unload \_ 1 n}}{{A}_{0} ( {∅}_{0} )} \\ \frac{{UF}_{unload \_ 12}}{{A}_{0} ( {∅}_{0} )} & \frac{{UF}_{unload \_ 22}}{{A}_{0} ( {∅}_{0} )} & \frac{{UF}_{unload \_ 23}}{{A}_{0} ( {∅}_{0} )} & … & \frac{{UF}_{unload \_ 2 n}}{{A}_{0} ( {∅}_{0} )} \\ \frac{{UF}_{unload \_ 13}}{{A}_{0} ( {∅}_{0} )} & \frac{{UF}_{unload \_ 23}}{{A}_{0} ( {∅}_{0} )} & \frac{{UF}_{unload \_ 33}}{{A}_{0} ( {∅}_{0} )} & … & \frac{{UF}_{unload \_ 3 n}}{{A}_{0} ( {∅}_{0} )} \\ ⋯ & ⋯ & ⋯ & ⋯ & ⋯ \\ \frac{{UF}_{unload \_ n 1}}{{A}_{0} ( {∅}_{0} )} & \frac{{UF}_{unload \_ n 2}}{{A}_{0} ( {∅}_{0} )} & \frac{{UF}_{unload \_ n 3}}{{A}_{0} ( {∅}_{0} )} & … & \frac{{UF}_{unload \_ n n}}{{A}_{0} ( {∅}_{0} )}\end{matrix} ] .$$

FIG. 9 is a flowchart illustrating an exemplary process 900 for determining a second forward coefficient, a second reverse coefficient, and a second coupling coefficient according to some embodiments of the present disclosure according to some embodiments of the present disclosure. In some embodiments, one or more operations of the process 900 may be performed to achieve at least part of operation 730 as described in connection with FIG. 7.

In 910, the processing device 120 (e.g., the determination module 220) may obtain a plurality of second RF parameter vectors.

In some embodiments, the plurality of second RF parameter vectors may be similar to the plurality of first RF parameter vectors described elsewhere in the present disclosure. See, e.g., descriptions of the plurality of first RF parameter vectors in connection with 810 of FIG. 8. For example, an element of each of the plurality of second RF parameters vectors may include RF parameters of an RF waveform to be transmitted into one of the plurality of system channels. The plurality of second RF parameter vectors may be linearly independent. In some embodiments, each of the plurality of second RF parameter vectors may be represented as a row vector. The plurality of second RF parameter vectors may form a matrix. For example, the plurality of second RF parameter vectors may form a second diagonal matrix.

In 920, for each of the plurality of second RF parameters vectors, the processing device 120 (e.g., the determination module 220) may obtain second reference forward signals, second reference reverse signals, and second reference coupling signals corresponding to the plurality of coil channels that are acquired by performing, based on the second RF parameter vector, a second MRI scan on the subject using the MRI scanner.

Merely by way of example, the plurality of second RF parameter vectors may form a second diagonal matrix whose elements on the diagonal are all A 0 (0 0), wherein A o denotes an amplitude value, and 0 0 denotes a phase value, that is, the diagonal matrix may be represented as

$$[ \begin{matrix}{A}_{0} ( {∅}_{0} ) & 0 & … & 0 \\ 0 & {A}_{0} ( {∅}_{0} ) & … & 0 \\ … & … . & … & 0 \\ 0 & … . & 0 & {A}_{0} ( {∅}_{0} )\end{matrix} ] ,$$

wherein, a row of the second diagonal matrix corresponds to a second RF parameter vector. If a count of the RF channels is n, n MRI scans may need to be performed on the subject based on the second diagonal matrix. Each MRI scan of the n MRI scans may be performed by transmitting an RF waveform with an amplitude value A₀ and a phase value ∅₀ via one of the plurality of system channels.

In 930, the processing device 120 (e.g., the determination module 220) may determine the second forward coefficient, the second reverse coefficient, and the second coupling coefficient based on the second reference forward signals, the second reference reverse signals, and the second reference coupling signals corresponding to the plurality of second RF parameter vectors.

As described in FIG. 3, the second reference forward signals, the second reference reverse signals, and the second reference coupling signals may be subject to analog-to-digital conversions and quadrature demodulations to provide second forward data, second reverse data, and second coupling data. Merely by way of example, second forward data, second reverse data, and second coupling data obtained by transmitting an RF waveform with an amplitude value A o and a phase value ∅₀ via the first system channel may be [UF_{load_11}, UF_{load_21}, . . . , UF_{load_n1}], [UR_{load_11}, UR_{load_21}, . . . , UR_{load_n1}], [I_{load_11}, I_{load_21}, . . . , I_{load_n1}], respectively; second forward data, second reverse data, and second coupling data obtained by transmitting an RF waveform with an amplitude value A₀ and a phase value ∅₀ via the second system channel may be [UF_{load_12}, UF_{load_22}, . . . , UF_{load_n2}], [UR_{load_12}, UR_{load_22}, . . , UR_{load_n2}], [I_{load_12}, I_{load_22}, . . . , I_{load_n2}], respectively; . . . ; second forward data, second reverse data, and second coupling data obtained by transmitting an RF waveform with an amplitude value A₀ and a phase value ∅₀ via the nth system channel may be [UF_{load _1n}, UF_{load _2n}, . . . , UF_{load_nn}], [UR_{load_1n}, UR_{load_2n}, . . . , UR_{load_nn}], [I_{load_1n}, I_{load_2n}, . . . , I_{load_nn}] respectively. The first subscript and second subscript of each of the second forward data, the second reverse data, and the second coupling data denote which coil channel and which system channel are involved for transmitting the RF signal, respectively.

The processing device 120 may determine the second forward coefficient, the second reverse coefficient, and the second coupling coefficient based on the second forward data, the second reverse data, and the second coupling data corresponding to the plurality of RF parameter vectors. For example, the second forward coefficient M4 may be represented as

$$[ \begin{matrix}\frac{{UF}_{load \_ 11}}{{A}_{0} ( {∅}_{0} )} & \frac{{UF}_{load \_ 12}}{{A}_{0} ( {∅}_{0} )} & \frac{{UF}_{load \_ 13}}{{A}_{0} ( {∅}_{0} )} & … & \frac{{UF}_{load \_ n 1}}{{A}_{0} ( {∅}_{0} )} \\ \frac{{UF}_{load \_ 12}}{{A}_{0} ( {∅}_{0} )} & \frac{{UF}_{load \_ 22}}{{A}_{0} ( {∅}_{0} )} & \frac{{UF}_{load \_ 23}}{{A}_{0} ( {∅}_{0} )} & … & \frac{{UF}_{load \_ n 2}}{{A}_{0} ( {∅}_{0} )} \\ \frac{{UF}_{load \_ 31}}{{A}_{0} ( {∅}_{0} )} & \frac{{UF}_{load \_ 32}}{{A}_{0} ( {∅}_{0} )} & \frac{{UF}_{load \_ 33}}{{A}_{0} ( {∅}_{0} )} & … & \frac{{UF}_{load \_ n 3}}{{A}_{0} ( {∅}_{0} )} \\ ⋯ & ⋯ & ⋯ & ⋯ & ⋯ \\ \frac{{UF}_{load \_ n 1}}{{A}_{0} ( {∅}_{0} )} & \frac{{UF}_{load \_ n 2}}{{A}_{0} ( {∅}_{0} )} & \frac{{UF}_{load \_ n 3}}{{A}_{0} ( {∅}_{0} )} & … & \frac{{UF}_{load \_ nn}}{{A}_{0} ( {∅}_{0} )}\end{matrix} ] .$$

The second reverse coefficient M5 may be represented as

$$[ \begin{matrix}\frac{{UF}_{load \_ 11}}{{A}_{0} ( {∅}_{0} )} & \frac{{UF}_{load \_ 12}}{{A}_{0} ( {∅}_{0} )} & \frac{{UF}_{load \_ 13}}{{A}_{0} ( {∅}_{0} )} & … & \frac{{UF}_{load \_ n 1}}{{A}_{0} ( {∅}_{0} )} \\ \frac{{UF}_{load \_ 12}}{{A}_{0} ( {∅}_{0} )} & \frac{{UF}_{load \_ 22}}{{A}_{0} ( {∅}_{0} )} & \frac{{UF}_{load \_ 23}}{{A}_{0} ( {∅}_{0} )} & … & \frac{{UF}_{load \_ n 2}}{{A}_{0} ( {∅}_{0} )} \\ \frac{{UF}_{load \_ 31}}{{A}_{0} ( {∅}_{0} )} & \frac{{UF}_{load \_ 32}}{{A}_{0} ( {∅}_{0} )} & \frac{{UF}_{load \_ 33}}{{A}_{0} ( {∅}_{0} )} & … & \frac{{UF}_{load \_ n 3}}{{A}_{0} ( {∅}_{0} )} \\ ⋯ & ⋯ & ⋯ & ⋯ & ⋯ \\ \frac{{UF}_{load \_ n 1}}{{A}_{0} ( {∅}_{0} )} & \frac{{UF}_{load \_ n 2}}{{A}_{0} ( {∅}_{0} )} & \frac{{UF}_{load \_ n 3}}{{A}_{0} ( {∅}_{0} )} & … & \frac{{UF}_{load \_ nn}}{{A}_{0} ( {∅}_{0} )}\end{matrix} ] .$$

The coupling coefficient M6 may be represented as

$$[ \begin{matrix}\frac{{UF}_{load \_ 11}}{{A}_{0} ( {∅}_{0} )} & \frac{{UF}_{load \_ 12}}{{A}_{0} ( {∅}_{0} )} & \frac{{UF}_{load \_ 13}}{{A}_{0} ( {∅}_{0} )} & … & \frac{{UF}_{load \_ n 1}}{{A}_{0} ( {∅}_{0} )} \\ \frac{{UF}_{load \_ 12}}{{A}_{0} ( {∅}_{0} )} & \frac{{UF}_{load \_ 22}}{{A}_{0} ( {∅}_{0} )} & \frac{{UF}_{load \_ 23}}{{A}_{0} ( {∅}_{0} )} & … & \frac{{UF}_{load \_ n 2}}{{A}_{0} ( {∅}_{0} )} \\ \frac{{UF}_{load \_ 31}}{{A}_{0} ( {∅}_{0} )} & \frac{{UF}_{load \_ 32}}{{A}_{0} ( {∅}_{0} )} & \frac{{UF}_{load \_ 33}}{{A}_{0} ( {∅}_{0} )} & … & \frac{{UF}_{load \_ n 3}}{{A}_{0} ( {∅}_{0} )} \\ ⋯ & ⋯ & ⋯ & ⋯ & ⋯ \\ \frac{{UF}_{load \_ n 1}}{{A}_{0} ( {∅}_{0} )} & \frac{{UF}_{load \_ n 2}}{{A}_{0} ( {∅}_{0} )} & \frac{{UF}_{load \_ n 3}}{{A}_{0} ( {∅}_{0} )} & … & \frac{{UF}_{load \_ nn}}{{A}_{0} ( {∅}_{0} )}\end{matrix} ] .$$

FIG. 10 is a flowchart illustrating an exemplary process 1000 for calibrating relationships between RF signals of channels for transmitting RF signals according to some embodiments of the present disclosure. In some embodiments, the process 1000 may be implemented in the MRI system 100 illustrated in FIG. 1. For example, the process 1000 may be stored in a storage (e.g., the storage device 130) as a form of instructions, and invoked and/or executed by the processing device 120 (e.g., one or more modules as illustrated in FIG. 2). The operations of the illustrated process presented below are intended to be illustrative. In some embodiments, the process 1000 may be accomplished with one or more additional operations not described, and/or without one or more of the operations discussed. Additionally, the order in which the operations of the process 1000 as illustrated in FIG. 10 and described below is not intended to be limiting.

As used herein, an RF signal transmitted via a system channel refers to an RF waveform, and an RF signal transmitted via a coil channel I refers to an RF excitation pulse.

In 1010, the processing device 120 (e.g., the acquisition module 210) may obtain a plurality of sets of image data. Each of at least some sets of the plurality of sets of image data may be acquired by performing an MRI scan using an MRI scanner.

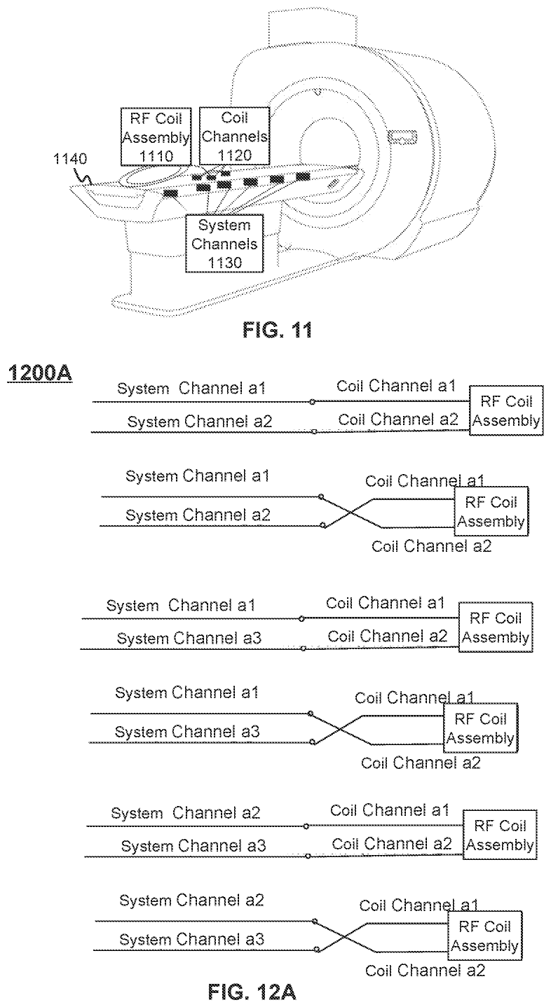

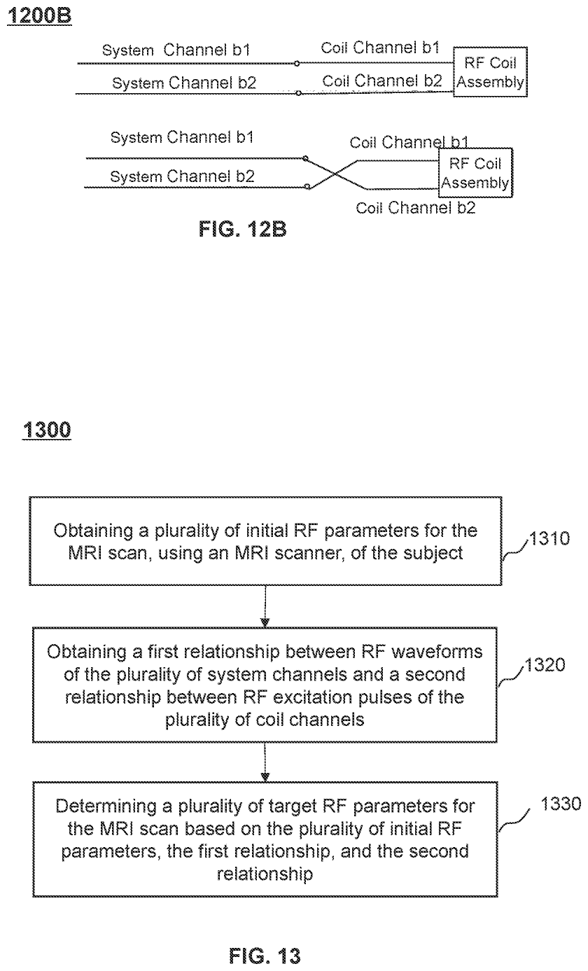

In some embodiments, the MR scanner may be the MR scanner 110 described in connection with FIG. 1. The MRI scanner may include a plurality of system channels. A system channel may be capable of being operably connected with any one coil channel of a plurality of coil channels of an RF coil assembly of the MRI scanner to form one of a plurality of RF channels of the MRI scanner. The RF coil assembly may be a detachable RF coil assembly. That is, the RF coil assembly may be capable of being removed from the MRI scanner. A coil of the RF coil assembly may be operably connected to one of different system channels for different MRI scans. In some embodiments, a count of the plurality of system channels may be greater than or equal to a count of the plurality of coil channels. For example, FIG. 11 is a schematic illustrating an exemplary coil channels and system channels of an MRI scanner according to some embodiments of the present disclosure. As shown in FIG. 11, the MRI scanner includes 6 system channels 1130 arranged on a table 1140 of the MRI scanner. The MRI scanner includes a detachable RF coil assembly 1110 including 3 coil channels 1120. As another example, FIG. 12A is a schematic illustrating exemplary RF channels of an MRI scanner 1200A according to some embodiments of the present disclosure. As shown in FIG. 12A, the MRI scanner 1200A includes a coil channel a1, a coil channel a2, a system channel a1, a system channel a2, and a system channel a3. Under a first connection mode, the coil channel al and the system channel al may be operably connected to form an RF channel a1; the coil channel a2 and the system channel a2 may be operably connected to form an RF channel a2. Under a second connection mode, the coil channel a2 and the system channel al may be operably connected to form an RF channel a3; the coil channel a1 and the system channel a2 may be operably connected to form an RF channel a4. Under a third connection mode, the coil channel a1 and the system channel a1 may be operably connected to form an RF channel a5; the coil channel a2 and the system channel a2 may be operably connected to form an RF channel a6. Under a fourth connection mode, the coil channel a2 and the system channel al may be operably connected to form an RF channel a7; the coil channel al and the system channel a3 may be operably connected to form an RF channel a8. Under a fifth connection mode, the coil channel al and the system channel a2 may be operably connected to form an RF channel a9; the coil channel a2 and the system channel a3 may be operably connected to form an RF channel a10. Under a sixth connection mode, the coil channel a2 and the system channel a2 may be operably connected to form an RF channel a11; the coil channel al and the system channel a3 may be operably connected to form an RF channel a12. As still another example, FIG. 12B is a schematic illustrating exemplary RF channels of an MRI scanner 1200B according to some embodiments of the present disclosure. As shown in FIG. 12B, the MRI scanner 1200B includes a coil channel b1, a coil channel b2, a system channel b1, and a system channel b2. Under a first connection mode, the coil channel b1 and the system channel b1 may be operably connected to form an RF channel b1; the coil channel b2 and the system channel b2 may be operably connected to form an RF channel b2. Under a second connection mode, the coil channel b2 and the system channel b1 may be operably connected to form an RF channel b3; the coil channel b1 and the system channel b2 may be operably connected to form an RF channel b4.

In some embodiments, each set of image data may be acquired by performing an MRI scan on a reference subject using the MRI scanner. Exemplary reference subject may include a water phantom, an agar phantom, etc. The plurality of sets of image data may include MR signals (e.g., free induction decay (FID) signals), image data in an image domain, or k-space data, etc.

In some embodiments, for each of the plurality of sets of image data, the set of image data may be acquired by transmitting a reference RF waveform via one of the plurality of RF channels. That is, the MRI scan for acquiring the set of image data may be performed by transmitting a reference RF waveform via one of the plurality of RF channels. The reference RF waveform may refer to an RF waveform generated by an RF generator. In some embodiments, the reference RF waveforms for acquiring the plurality of sets of image data may have a same amplitude value and a same phase value. Merely by way of example, as shown in FIG. 12B, a set of image data W/ may be acquired by transmitting a reference RF waveform K1 via the RF channel b1. A set of image data W2 may be acquired by transmitting a reference RF waveform K2 via the RF channel b2. A set of image data W3 may be acquired by transmitting a reference RF waveform K3 via the RF channel b3. A set of image data W4 may be acquired by transmitting a reference RF waveform K4 via the RF channel b4.

In some embodiments, the reference RF waveforms K1-K4 may have a same amplitude value and a same phase value.

In 1020, the processing device 120 (e.g., the determination module 220) may determine, based on the plurality of sets of image data, at least one of a first relationship between RF waveforms of the plurality of system channels and a second relationship between RF excitation pulses of the plurality of coil channels. The first relationship and the second relationship may be configured to provide a plurality of RF parameters for an MRI scan using the MRI scanner.

In some embodiments, the processing device 120 may determine whether the first relationship needs to be determined. For example, if the first relationship has been determined based on the same RF coil assembly or another RF coil assembly, the processing device 120 may determine the first relationship does not need to be determined. As another example, the processing device 120 may determine whether the first relationship needs to be determined according to a user instruction. In response to determining that the first relationship needs to be determined, the processing device 120 may determine the first relationship and the second relationship. In response to determining that the first relationship does not need to be determined, the processing device 120 may only determine the second relationship.

For brevity, the first relationship between RF waveforms of the plurality of system channels may be referred to as the first relationship between the plurality of system channels, and the second relationship between RF excitation pulses of the plurality of coil channels may be referred to as the second relationship between the plurality of coil channels.

In some embodiments, each of the plurality of sets of image data may include amplitude information. The first relationship may include a first amplitude gain relationship between amplitude gains of the RF waveforms of the plurality of system channels. The second relationship may include a second amplitude gain relationship between amplitude gains of the RF excitation pulses of the plurality of coil channels. Accordingly, the first relationship and the second relationship may be configured to provide amplitude values of a plurality of initial RF signals for the MRI scan. Each of the plurality of initial RF signals refers to an RF waveform to be transmitted into one system channel of the plurality of RF channels. For brevity, an amplitude gain of an RF signal of a channel (e.g., an RF channel, a system channel, a coil channel) may be referred to as an amplitude gain of the channel.

In some embodiments, each of the plurality of sets of image data may include phase information. The first relationship may include a first phase relationship between phase values of the RF waveforms of the plurality of system channels. The second relationship may include a second phase relationship between phase values of the RF excitation pulses of the plurality of coil channels. Accordingly, the first relationship and the second relationship may be configured to provide phase values of a plurality of initial RF signals for the MRI scan. Each of the plurality of initial RF signals refers to an RF waveform to be transmitted into one system channel of the plurality of RF channels. For brevity, a phase value of an RF signal of a channel (e.g., an RF channel, a system channel, a coil channel) may be referred to as a phase value of the channel.

In some embodiments, the processing device 120 may obtain a reference relationship between an RF signal of an RF channel and a set of image data obtained using the RF signal. For example, the reference relationship may include an amplitude reference relationship, a phase reference relationship, etc. The amplitude reference relationship refers to a relationship between an amplitude gain of an RF signal of an RF channel and an amplitude of a set of image data obtained using the RF signal. Exemplary amplitude reference relationships may include a linear relationship, a sine trigonometric function, etc. The phase reference relationship refers to a relationship between a phase value of an RF signal of an RF channel and a phase value of a set of image data obtained using the RF signal. Exemplary phase reference relationships may include a sum relationship, etc. The processing device 120 may determine at least one of the first relationship or the second relationship based on the plurality of sets of image data and the reference relationship.

Merely by way of example, the processing device 120 may determine the first relationship between the system channels b1 and b2, and the second relationship between the coil channels b1 and b2 based on the sets of image data W1-W4 obtained in operation 1010. The processing device 120 may obtain the sets of image data W1-W4 as shown in Table 1.

TABLE 1
the sets of image data W1-W4

| Image | | Amplitude | Phase |
|---|---|---|---|
| data | RF channel | value | value |
| W1 | RF channel b1 (coil channel b1 | A1 | P1 |
| | and system channel b1) | | |
| W2 | RF channel b2 (coil channel b2 | A2 | P2 |
| | and system channel b2) | | |
| W3 | RF channel b3 (coil channel b2 | A3 | P3 |
| | and system channel b1) | | |
| W4 | RF channel b4 (coil channel b1 | A4 | P4 |
| | and system channel b2) | | |

If the amplitude reference relationships is a linear relationship, the amplitude values A1, A2, A3, and A4 may satisfy Equation (14) and Equation (15) below:

$$\begin{matrix}\frac{A 1}{A 2} = \frac{C 1 * E 1}{C 2 * E 2} , & ( 14 ) \\ \frac{A 3}{A 4} = \frac{C 1 * E 2}{C 2 * E 1} , & ( 15 )\end{matrix}$$

where C1 denotes an amplitude gain of the system channel b1, C2 denotes an amplitude gain of the system channel b2, E1 denotes an amplitude gain of the coil channel b1, and E2 denotes an amplitude gain of the coil channel b2.

The processing device 120 may determine a first amplitude gain relationship between the system channels b1 and b2 as

$$\frac{C 1}{C 2} = \sqrt{\frac{A 1 \times A 3}{A 2 \times A 4}} ,$$

and a second amplitude gain relationship between the coil channels b1 and b2 as

$$\frac{E 1}{E 2} = \sqrt{\frac{A 1 \times A 4}{A 2 \times A 3}} ,$$

according to the Equation (14) and Equation (15), respectively.

If the phase reference relationships is a sum relationship, the phase values P1, P2, P3, and P4 may satisfy Equation (16) and Equation (17) below:

P1−P2=(D1+F1)−(D2+F2), (16)

P3−P4=(D1+F2)−(D2+F1), (17)

where D1 denotes a phase value of the system channel b1, D2 denotes a phase value of the system channel b2, F1 denotes a phase value of the coil channel b1, and F2 denotes a phase value of the coil channel b2.

The processing device 120 may determine a first phase relationship between the system channels b1 and b2 as

$$D 1 - D 2 = \frac{P 1 - P 2 + P 3 - P 4}{2} ,$$

and a second phase relationship between the coil channels b1 and b2 as

$$F 1 - F 2 = \frac{P 1 - P 2 - P 3 + P 4}{2} ,$$

according to the Equation (16) and Equation (17), respectively.

In some embodiments, the processing device 120 may determine a third relationship between the plurality of RF channels based on the first relationship between the plurality of system channels and the second relationship between the plurality of coil channels. More descriptions for the determination of the third relationship may be found elsewhere in the present disclosure. See, e.g., operation 1330 in FIG. 13 and relevant descriptions thereof.

In some embodiments, the processing device 120 may obtain a plurality of initial RF parameters for a target MRI scan of a subject using the MRI scanner. The processing device 120 may determine a plurality of target RF parameters for the target MRI scan based on the plurality of initial RF parameters, the first relationship, and the second relationship. More descriptions for the determination of a plurality of target RF parameters for a target MRI scan may be found elsewhere in the present disclosure (e.g., FIG. 13 and the descriptions thereof).

Compared with the conventional approach for calibrating relationships between RF signals as described elsewhere in the present disclosure, according to some embodiments of the present disclosure, the first relationship between the plurality of system channels and the second relationship between the plurality of coil channels may be determined, and further the third relationship between the plurality of RF channels may be determined based on the first relationship and the second relationship, which may achieve the calibration of relationships between RF channels corresponding to all connection modes by performing only one calibration, thereby improving the applicability of the detachable RF coil assembly and/or taking advantage of the versatility achievable by the detachable RF coil assembly.

FIG. 13 is a flowchart illustrating an exemplary process 1300 for determining a plurality of target RF parameters for an MRI scan of a subject according to some embodiments of the present disclosure. In some embodiments, the process 1300 may be implemented in the MRI system 100 illustrated in FIG. 1. For example, the process 1300 may be stored in a storage (e.g., the storage device 130) as a form of instructions, and invoked and/or executed by the processing device 120 (e.g., one or more modules as illustrated in FIG. 2). The operations of the illustrated process presented below are intended to be illustrative. In some embodiments, the process 1300 may be accomplished with one or more additional operations not described, and/or without one or more of the operations discussed. Additionally, the order in which the operations of the process 1300 as illustrated in FIG. 13 and described below is not intended to be limiting.

In 1310, the processing device 120 (e.g., the acquisition module 210) may obtain a plurality of initial RF parameters for the MRI scan, using an MRI scanner, of the subject.

In some embodiments, the MR scanner may be the MR scanner 110 described in connection with FIG. 1. In some embodiments, the MR scanner may the same as or similar to the MR scanner described in connection with operation 1010 in FIG. 10. The MRI scanner may include a plurality of system channels. A system channel may be capable of being operably connected with any one coil channel of a plurality of coil channels of an RF coil assembly of the MRI scanner to form one of a plurality of RF channels of the MRI scanner. The RF coil assembly may be a detachable RF coil assembly. That is, the RF coil assembly may be capable of being removed from the MRI scanner. A coil of the RF coil assembly may be operably connected to one of different system channels for different MRI scans. In some embodiments, a count of the plurality of system channels may be greater than or equal to a count of the plurality of coil channels. The plurality of initial RF parameters for the MRI scan may include initial RF parameters corresponding to each of a plurality of target RF channels for performing the MRI scan. The initial RF parameters corresponding to a target RF channel may include an initial amplitude value and an initial phase value of an RF waveform to be transmitted into a target system channel of the target RF channel.

In some embodiments, the processing device 120 may obtain the plurality of initial RF parameters from a component (e.g., the storage device 130, the terminal(s) 140, etc.) of the MRI system 100.

In 1320, the processing device 120 (e.g., the acquisition module 210) may obtain a first relationship between RF waveforms of the plurality of system channels and a second relationship between RF excitation pulses of the plurality of coil channels.

In some embodiments, the first relationship and the second relationship may be previously generated and stored in a storage device (e.g., the storage device 130 or an external source). The processing device 120 may retrieve the first relationship and the second relationship directly from the storage device. In some embodiments, the processing device 120 may determine the first relationship and the second relationship in a similar manner described in FIG. 10.

In 1330, the processing device 120 (e.g., the determination module 220) may determine a plurality of target RF parameters for the MRI scan based on the plurality of initial RF parameters, the first relationship, and the second relationship.

In some embodiments, the plurality of target RF parameters may include at least one of a target amplitude value and a target phase value of an RF waveform to be transmitted into a target system channel of each target RF channel for performing the MRI scan.

In some embodiments, the processing device 120 may determine a third relationship between RF signals of the plurality of target RF channels (also referred to as a third relationship between the plurality of target RF channels) based on the first relationship. In some embodiments, the third relationship may include a third amplitude gain relationship between amplitude gains of the RF signals of the plurality of target RF channels. In some embodiments, the third relationship may include a third phase relationship between phase values of the RF signals of the plurality of target RF channels. For brevity, an amplitude gain, a phase (or a phase value) of an RF signal of a channel (e.g., an RF channel, a system channel, a coil channel) may be referred to as an amplitude gain, a phase (or a phase value) of the channel, respectively. Merely by way of example, if the RF channels b1 and b2 described in FIG. 10 and FIG. 12B are the target RF channels for the MRI scan, the first amplitude gain relationship between the system channels b1 and b2 is C1/C2=1/2 , and the second amplitude gain relationship between the coil channels b1 and b2 is

$$\frac{E 1}{E 2} = \frac{2}{3} ,$$

the third amplitude gain relationship between the RF channels b1 and b2 may be

$$\frac{Rm 1}{Rm 2} = \frac{C 1 * E 1}{C 2 * E 2} = \frac{1}{2} * \frac{2}{3} = \frac{1}{3} ,$$

wherein C1 denotes an amplitude gain of the system channel b1, C1 denotes an amplitude gain of the system channel b2, E1 denotes an amplitude gain of the coil channel b1, E2 denotes an amplitude gain of the coil channel b1, Rm1 denotes an amplitude gain of the RF channel b1, and Rm2 denotes an amplitude gain of the RF channel b2. If the first phase relationship between the system channels b1 and b2 is D1−D2=30°, and the second phase relationship between the coil channels b1 and b2 is F1−F2=20°, the third phase relationship between the RF channels b1 and b2 may be Rf1−Rf2=(D1+F1)−(D2+F2)=(D1−D2)+(F1−F2)=30°+20°=50°, wherein D1 denotes a phase value of the system channel b1, D2 denotes a phase value of the system channel b2, F1 denotes a phase value of the coil channel b1, F2 denotes a phase value of the coil channel b2, Rf1 denotes a phase value of the RF channel b1, and Rf2 denotes a phase value of the RF channel b2.

In some embodiments, the processing device 120 may obtain a preset condition associated with the plurality of target RF parameters. The preset condition refers to a condition that a plurality of RF parameters of the RF signals satisfy after RF signals (i.e., the RF waveforms to be transmitted into target system channels) generated based on the plurality of target RF parameters are transmitted through the target RF channels. For brevity, after RF signals (i.e., the RF waveforms to be transmitted into target system channels) generated based on the plurality of target RF parameters are transmitted through the target RF channels, the RF signals may be referred to as the transmitted RF signals. For example, the preset condition may be that amplitude values and phase values of the transmitted RF signals satisfy preset conditions. The preset condition may be set manually by a user (e.g., an engineer) according to an actual need or a default setting of the MRI system 100. The processing device 120 may obtain the preset condition from a component (e.g., the storage device 130, the terminal(s) 140, etc.) of the MRI system 100.

In some embodiments, the processing device 120 may determine the plurality of target RF parameters for the MRI scan based on the plurality of initial RF parameters, the third relationship, and the preset condition. The processing device 120 may determine, based on the third relationship and the preset condition, a fourth relationship that the plurality of target RF parameters satisfy. Further, the processing device 120 may determine the plurality of target RF parameters based on the plurality of initial RF parameters and the fourth relationship. The processing device 120 may adjust one or more of the plurality of initial RF parameters, so that the plurality of adjusted RF parameters satisfy the fourth relationship. The processing device 120 may designate the plurality of adjusted RF parameters as the plurality of target RF parameters.

For example, as aforementioned, if the RF channels b1 and b2 described in FIG. 10 and FIG. 12B are the target RF channels for the MRI scan, the third amplitude gain relationship between the RF channels b1 and b2

$$\frac{Rm 1}{Rm 2} = \frac{1}{3} ,$$

the preset condition includes that a ratio of an amplitude value of the transmitted RF signal corresponding to the RF channel b1 and an amplitude value of the transmitted RF signal corresponding to the RF channel b2 may be 1/2; that is,

$$\frac{m 1}{m 2} * \frac{1}{3} = \frac{1}{2} ,$$

wherein m1 and m2 denote target amplitude values corresponding to the RF channels b1 and b2, respectively, and the fourth relationship that target amplitude values of the corresponding to the RF channels b1 and b2 may be

$$\frac{m 1}{m 2} = \frac{1}{2} / \frac{1}{3} = \frac{3}{2} .$$

Further, the processing device 120 may adjust at least one of initial amplitude values corresponding to the RF channels b1 and b2, so that a ratio of the adjusted amplitude values corresponding to the RF channels b1 and b2 is 3/2. The processing device 120 may designate the adjusted amplitude values corresponding to the RF channels b1 and b2 as the target amplitude values corresponding to the RF channels b1 and b2. As another example, the preset condition includes that a ratio of an amplitude value of the transmitted RF signal corresponding to the RF channel b1 and an amplitude value of the transmitted RF signal corresponding to the RF channel b2 may be 1/1; that is,

$$\frac{m 1}{m 2} * \frac{1}{3} = \frac{1}{2} ,$$

the fourth relationship that target amplitude values of the corresponding to the RF channels b1 and b2 may be

$$\frac{m 1}{m 2} = \frac{1}{1} / \frac{1}{3} = \frac{3}{1} .$$

Further, the processing device 120 may adjust at least one of initial amplitude values corresponding to the RF channels b1 and b2, so that a ratio of the adjusted amplitude values corresponding to the RF channels b1 and b2 is 3/1. The processing device 120 may designate the adjusted amplitude values corresponding to the RF channels b1 and b2 as the target amplitude values corresponding to the RF channels b1 and b2.

As a further example, as aforementioned, if the RF channels 1 and 2 described in FIG. 10 and FIG. 12A are the target RF channels for the MRI scan, the third phase relationship between the RF channels b1 and b2 may be Rf1−Rf2=50°, the preset condition is that phase values of the transmitted RF signals corresponding to the RF channels b1 and b2 may be the same; that is, P1+Rf1=P2+Rf2, wherein P1 and P2 denote target phase values corresponding to the RF channels b1 and b2, respectively, the fourth relationship that target phase values of the corresponding to the RF channels b1 and b2 may be P2−P1=Rf1−Rf2=5020 . Further, the processing device 120 may adjust at least one of initial phase values corresponding to the RF channels b1 and b2, so that the adjusted phase value corresponding to the target RF channel 2 minus the adjusted phase value corresponding to the RF channel b1 equals 50°. The processing device 120 may designate the adjusted amplitude values corresponding to the RF channels b1 and b2 as the target amplitude values corresponding to the RF channels b1 and b2.

According to some embodiments of the present disclosure, the plurality of target RF parameters for the MRI scan may be determined based on the plurality of initial RF parameters, the first relationship, the second relationship, and/or the preset condition, which may obliviate the need for repeated calibrations for different connection modes of the system channels and the coil channels, thereby allowing flexible connection modes while achieving a relatively high efficiency and accurate target RF parameters, which in turn may improve the efficiency, versatility, and accuracy of transmitting RF signals to satisfy user needs.

It will be apparent to those skilled in the art that various changes and modifications can be made in the present disclosure without departing from the spirit and scope of the disclosure. In this manner, the present disclosure may be intended to include such modifications and variations if the modifications and variations of the present disclosure are within the scope of the appended claims and the equivalents thereof.

1. A system, comprising:
at least one storage device including a set of instructions; and
at least one processor in communication with the at least one storage device, wherein when executing the set of instructions, the at least one processor is directed to cause the system to perform operations including:
obtaining a plurality of radiofrequency (RF) parameters for a magnetic resonance imaging (MRI) scan, using an MRI scanner, of a subject, the plurality of RF parameters including at least one RF parameter of an RF waveform to be transmitted into each of a plurality of system channels of the MRI scanner, wherein each of the plurality of system channels is connected to one of a plurality of coil channels of an RF coil assembly of the MRI scanner to form an RF channel;
determining, based on the plurality of RF parameters, a first power loss and a first current square factor of the RF coil assembly under an unloaded condition of the MRI scanner;
determining, based on the plurality of RF parameters, a total power loss of the MRI scan and a second current square factor of the RF coil assembly during the MRI scan;
determining, based on the first power loss, the first current square factor, and the second current square factor, a second power loss of the RF coil assembly during the MRI scan; and
determining, based on the total power loss and the second power loss, a specific absorption ratio (SAR) of the subject during the MRI scan.

2. The system of claim 1, wherein the determining, based on the plurality of RF parameters, a first power loss and a first current square factor of the RF coil assembly under an unloaded condition of the MRI scanner includes:
obtaining a first forward coefficient associated with forward signals of the RF coil assembly, a first reverse coefficient associated with reverse signals of the RF coil assembly, and a first coupling coefficient associated with coupling signals of the RF coil assembly; and
determining the first power loss and the first current square factor based on the plurality of RF parameters, the first forward coefficient, the first reverse coefficient, and the first coupling coefficient.

3. The system of claim 2, wherein the obtaining a first forward coefficient associated with forward signals of the RF coil assembly, a first reverse coefficient associated with reverse signals of the RF coil assembly, and a first coupling coefficient associated with coupling signals of the RF coil assembly includes:
obtaining a plurality of first RF parameter vectors, wherein
the plurality of first RF parameter vectors are linearly independent, and
an element of each of the plurality of first RF parameter vectors includes RF parameters of an RF waveform to be transmitted into one of the plurality of system channels;
for each of the plurality of first RF parameter vectors,
obtaining first reference forward signals, first reference reverse signals, and first reference coupling signals corresponding to the plurality of coil channels by performing, based on the first RF parameters vector, a first reference MRI scan under the unloaded condition of the MRI scanner; and
determining the first forward coefficient, the first reverse coefficient, and the first coupling coefficient based on the first reference forward signals, the first reference reverse signals, and the first reference coupling signals corresponding to the plurality of first RF parameter vectors.

4. The system of claim 3, wherein the plurality of first RF parameter vectors form a first diagonal matrix.

5. The system of claim 1, wherein the determining, based on the plurality of RF parameters, a total power loss of the MRI scan and a second current square factor of the RF coil assembly includes:
determining a second forward coefficient associated with forward signals of the RF coil assembly, a second reverse coefficient associated with reverse signals of the RF coil assembly, and a second coupling coefficient associated with coupling signals of the RF coil assembly; and
determining the total power loss of the MRI scan and the second current square factor of the RF coil assembly based on the plurality of RF parameters, the second forward coefficient, the second reverse coefficient, and the second coupling coefficient.

6. The system of claim 5, wherein the obtaining a second forward coefficient associated with forward signals of the RF coil assembly, a second reverse coefficient associated with reverse signals of the RF coil assembly, and a second coupling coefficient associated with coupling signals of the RF coil assembly includes:
obtaining a plurality of second RF parameter vectors, wherein
the plurality of second RF parameter vectors are linearly independent, and
an element of each of the plurality of second RF parameters vectors includes RF parameters of an RF waveform to be transmitted into one of the plurality of system channels;
for each of the plurality of second RF parameters vectors, obtaining second reference forward signals, second reference reverse signals, and second reference coupling signals corresponding to the plurality of coil channels by performing, based on the second RF parameter vector, a second reference MRI scan on the subject using the MRI scanner; and
determining the second forward coefficient, the second reverse coefficient, and the second coupling coefficient based on the second reference forward signals, the second reference reverse signals, and the second reference coupling signals corresponding to the plurality of second RF parameter vectors.

7. The system of claim 5, wherein the plurality of second RF parameter vectors form a second diagonal matrix.

8. The system of claim 1, wherein the determining, based on the plurality of RF parameters, a total power loss of the MRI scan and a second current square factor of the RF coil assembly includes:
determining whether the plurality of RF parameters satisfy a preset condition; and
in response to determining that the plurality of RF parameters satisfy the preset condition,
obtaining forward signals, reverse signals, and coupling signals corresponding to the plurality of coil channels collected during the MRI scan of the subject; and
determining the total power loss of the MRI scan and the second current square factor of the RE coil assembly based on the forward signals, the reverse signals, and the coupling signals corresponding to the plurality of coil channels.

9. The system of claim 8, wherein
the at least one RF parameter of an RF waveform to be transmitted into each of the plurality of system channels includes an amplitude value and a phase value of the RE waveform to be transmitted into the system channel; and
the preset condition includes:
a ratio between amplitude values of the system channel and the coil channel of each RF channel of the plurality of RF channels is the same among the plurality of RF channels during the MRI scan, and
a difference between phase values of the system channel and the coil channel of each RF channel of the plurality of system channels is the same among the plurality of RF channels during the MRI scan.

10. The system of claim 1, wherein the at least one processor is further directed to cause the system to perform the operations including:
in response to determining that a value of the SAR of the subject exceeds a threshold, adjusting the plurality of RF parameters.

11. A system, comprising:
at least one storage device including a set of instructions; and
at least one processor in communication with the at least one storage device, wherein when executing the set of instructions, the at least one processor is directed to cause the system to perform operations including:
obtaining a plurality of radiofrequency (RF) parameter vectors for a magnetic resonance imaging (MRI) scan using an MRI scanner, wherein
the plurality of RF parameter vectors are linearly independent, and
an element of each of the plurality of RF parameter vectors includes RF parameters of an RF waveform to be transmitted into one of a plurality of system channels of the MRI scanner;
for each of the plurality of RF parameter vectors, obtaining forward signals, reverse signals, and coupling signals corresponding to a plurality of coil channels of an RF coil assembly of the MRI scanner by performing, based on the RF parameters vector, an MRI scan under an unloaded condition of the MRI scanner; and
determining a forward coefficient associated with forward signals of the RF coil assembly, a reverse coefficient associated with reverse signals of the RF coil assembly, and a coupling coefficient associated with coupling signals of the RF coil assembly based on the forward signals, the reverse signals, and the coupling signals corresponding to the plurality of RF parameter vectors.

12. A system, comprising:
a radiofrequency (RF) generator including a plurality of system channels, configured to generate, based on a plurality of RE parameters, RF waveforms;
an RF coil assembly, configured to generate RF excitation pulses by applying the RF waveforms to the RE coil assembly to perform, using a magnetic resonance imaging (MRI) scanner, an MRI scan, the RF coil assembly including a plurality of coil channels, wherein each coil channel of the plurality of coil channels corresponds to one coil of a plurality of coils of the RE coil assembly and is operably connected to one system channel of the plurality of system channels;
a plurality of directional couplers, configured to collect forward signals and/or reverse signals of the RF coil assembly during the MRI scan, wherein each of the plurality of directional couplers is arranged between the RF generator and one coil of the plurality of coils of the RF coil assembly; and
a plurality of coupling probes, configured to collect coupling signals of the RF coil assembly during the MR1 scan.

13. The system of claim 12, further including a plurality of RF power amplifiers operably connected to the RF generator, the plurality of RF power amplifiers being configured to amplify the RF waveforms and transmit the amplified RF waveforms to the RF coil assembly.

14. The system of claim 12, further including a processing device, configured to determine a power loss of the RF coil assembly during the MRI scan based on the forward signals, the reverse signals, and the coupling signals of the RF coil assembly.

15. The system of claim 14, wherein the processing device includes an analog-to-digital converter, configured to obtain forward data, reverse data, and coupling data of the RF coil assembly by performing analog-to-digital conversions on the forward signals, the reverse signals, and the coupling signals of the RF coil assembly.

16. The system of claim 14, wherein the MRI scan is performed on a subject, and the processing device is configured to determine a specific absorption ratio (SAR) of the subject during the MRI of the subject based on the power loss of the RF coil assembly.

17. The system of claim 12, further including a controller, configured to control resonance or detuning of the RF coil assembly, or adjust the plurality of RF parameters according to the SAR of the subject.

18. The system of claim 11, wherein the plurality of RF parameter vectors form a diagonal matrix.

19. The system of claim 11, wherein the operations further include:
determining a first power loss and a first current square factor of the RF coil assembly under the unloaded condition of the MRI scanner based on the forward coefficient, the reverse coefficient, and the coupling coefficient;
determining, based on the RF parameters, a total power loss of the MRI scan and a second current square factor of the RF coil assembly during the MRI scan;
determining, based on the first power loss, the first current square factor, and the second current square factor, a second power loss of the RF coil assembly during the MRI scan; and
determining, based on the total power loss and the second power loss, a specific absorption ratio (SAR) of the subject during the MRI scan.

20. The system of claim 19, wherein the determining, based on the RF parameters, a total power loss of the MRI scan and a second current square factor of the RF coil assembly during the MRI scan includes:
determining a second forward coefficient associated with forward signals of the RF coil assembly, a second reverse coefficient associated with reverse signals of the RF coil assembly, and a second coupling coefficient associated with coupling signals of the RF coil assembly; and
determining the total power loss of the MRI scan and the second current square factor of the RF coil assembly based on the RF parameters, the second forward coefficient, the second reverse coefficient, and the second coupling coefficient.
